(19) United States
(12) Patent Application Publication
(10) Pub. No.: US 2024/0036389 A1
(43) Pub. Date: Feb. 1, 2024

(54) DECORATIVE SHEET, DISPLAY DEVICE, AND AUTOMOBILE INTERIOR MATERIAL

(71) Applicant: FUJIFILM Corporation, Tokyo (JP)

(72) Inventors: Makoto ISHIGURO, Minamiashigara-shi (JP); Yuichi HAYATA, Minamiashigara-shi (JP)

(73) Assignee: FUJIFILM Corporation, Tokyo (JP)

(21) Appl. No.: 18/478,027

(22) Filed: Sep. 29, 2023

Related U.S. Application Data
(63) Continuation of application No. PCT/JP2022/012250, filed on Mar. 17, 2022.

(30) Foreign Application Priority Data
Mar. 30, 2021 (JP) 2021-056616

(51) Int. Cl. G02F 1/1335

(52) U.S. Cl. CPC G02F 1/133543

(57) ABSTRACT

An object of the present invention is to provide: a decorative sheet having a small tint change depending on observation directions and having excellent visibility of a pattern in any observation direction during observation from a front direction and an oblique direction; and a display device and an automobile interior material including the decorative sheet. The decorative sheet according to the present invention includes: a circularly polarized light reflection layer; and a decorative layer that is disposed on the circularly polarized light reflection layer and where an opening portion is provided.

### CROSS-REFERENCE TO RELATED APPLICATIONS

This application is a Continuation of PCT International Application No. PCT/JP2022/012250 filed on Mar. 17, 2022, which claims priority under 35 U.S.C. § 119(a) to Japanese Patent Application No. 2021-056616 filed on Mar. 30, 2021. The above applications are hereby expressly incorporated by reference, in their entirety, into the present application.

### BACKGROUND OF THE INVENTION

### 1. Field of the Invention

The present invention relates to a decorative sheet, a display device, and an automobile interior material.

### 2. Description of the Related Art

In order to decorate surfaces of home electric appliances, business machines, automobile components, and the like, a decorative sheet is used. As the decorative sheet, the use of a decorative sheet including a cholesteric liquid crystal layer is considered. The cholesteric liquid crystal layer is obtained by immobilizing a cholesteric liquid crystalline phase and is known as a layer having properties in which at least either right circularly polarized light or left circularly polarized light in a specific wavelength range is selectively reflected.

For example, JP6744415B discloses a decorative sheet that includes a cholesteric liquid crystal layer and satisfies a predetermined relationship of reflectivity.

### SUMMARY OF THE INVENTION

The present inventors conducted an investigation on the decorative sheet including the cholesteric liquid crystal layer described in JP6744415B and found that, in a case where the decorative sheet is observed from the front direction and an oblique direction, the visibility of a pattern of the decorative sheet is excellent in any observation direction, but a change in the tint of the decorative sheet depending on observation directions may increase. As a result, the present inventors clarified that there is a room for improvement.

Accordingly, an object of the present invention is to provide: a decorative sheet having a small tint change depending on observation directions and having excellent visibility of a pattern in any observation direction during observation from the front direction and an oblique direction; and a display device and an automobile interior material including the decorative sheet.

In order to achieve the object, the present inventor conducted a thorough investigation and found that, by using a decorative sheet including a circularly polarized light reflection layer and a decorative layer that is disposed on the circularly polarized light reflection layer and where an opening portion, a tint change depending on observation directions is small, and the visibility of a pattern in any observation direction is excellent, thereby completing the present invention.

That is, the present inventors found that the object can be achieved by the following configurations.

[1] A decorative sheet comprising:
a circularly polarized light reflection layer; and
a decorative layer that is disposed on the circularly polarized light reflection layer and where an opening portion is provided.

[2] The decorative sheet according to [1],
in which the circularly polarized light reflection layer exhibits selective reflection in a visible range and has a stripe pattern of bright portions and dark portions observed with a scanning electron microscope in a cross-section,
the stripe pattern has a waving structure, and
the waving structure refers to a structure in which at least one region M where an absolute value of a tilt angle of a continuous line of the bright portions or the dark portions in the stripe pattern with respect to a plane of the circularly polarized light reflection layer is 5° or more is present, and peaks or valleys having a tilt angle of 0° are specified at two points most adjacent to each other with the region M sandwiched between the two points.

[3] The decorative sheet according to [2],
in which an average value of peak-to-peak distances of the waving structure is 0.5 to 50 μm,
the peak-to-peak distance of the waving structure refers to a value obtained by measuring a distance in a plane direction of the circularly polarized light reflection layer between the peaks or the valleys having a tilt angle of 0° at the two points most adjacent to each other with the region M sandwiched between the two points and calculating an arithmetic mean value of distance values at all film thicknesses in a case where a length of the circularly polarized light reflection layer in a major axis direction of the cross-section is 100 μm.

[4] The decorative sheet according to any one of [1] to [3],
in which a maximum value of an integral reflectivity of the circularly polarized light reflection layer excluding a specular reflection component in a wavelength range of 380 to 780 nm is 7% or more.

[5] The decorative sheet according to any one of [1] to [4],
in which the circularly polarized light reflection layer includes a cholesteric liquid crystal layer having a pitch gradient structure that is a structure in which a helical pitch changes in a thickness direction.

[6] The decorative sheet according to any one of [1] to [5],
in which a diameter of the opening portion is 500 μm or less.

[7] The decorative sheet according to any one of [1] to [6],
in which a visibility-corrected transmittance of the decorative layer in a visible range is 70% or less.

[8] The decorative sheet according to any one of [1] to [7],
in which a visibility-corrected transmittance of circularly polarized light in a visible range is 30% or more.

[9] The decorative sheet according to any one of [1] to [8], further comprising:
a λ/4 retardation plate or a circularly polarizing plate on a surface side of the circularly polarized light reflection layer opposite to the decorative layer.

[10] A display device comprising:
a display element; and
the decorative sheet according to any one of [1] to [9] that is disposed on the display element.

[11] The display device according to [10],
in which emitted light of the display element is linearly polarized light.

[12] The display device according to [11], which is a liquid crystal display device or an organic electroluminescent display device.

[13] An automobile interior material comprising:
the decorative sheet according to any one of [1] to [9] or the display device according to any one of [10] to [12].

According to the present invention, it is possible to provide: a decorative sheet having a small tint change depending on observation directions and having excellent visibility of a pattern in any observation direction during observation from the front direction and an oblique direction; and a display device and an automobile interior material including the decorative sheet.

### BRIEF DESCRIPTION OF THE DRAWINGS

FIG. 1 is a schematic cross-sectional view showing an example of a decorative sheet according to the present invention.

FIG. 2 is a conceptual diagram showing light reflection from a cholesteric liquid crystal layer.

FIG. 3 is a conceptual diagram showing light reflection from the cholesteric liquid crystal layer.

FIG. 4 is a conceptual diagram showing a peak-to-peak distance of a flapping structure.

FIG. 5 is a partially enlarged view schematically showing a surface of a decorative layer.

### DESCRIPTION OF THE PREFERRED EMBODIMENTS

Hereinafter, the details of the present invention will be described.

The following description regarding components has been made based on a representative embodiment of the present invention. However, the present invention is not limited to the embodiment.

In the present specification, numerical ranges represented by “to” include numerical values before and after “to” as lower limit values and upper limit values.

In addition, in the present specification, a liquid crystal composition and a liquid crystal compound include those that do not exhibit liquid crystal properties by curing or the like.

[Decorative Sheet]

A decorative sheet according to an embodiment of the present invention comprises: a circularly polarized light reflection layer; and a decorative layer that is disposed on the circularly polarized light reflection layer and where an opening portion is provided.

The decorative sheet according to the embodiment of the present invention has a small tint change depending on observation directions and has excellent visibility of a pattern in any observation direction during observation from the front direction and an oblique direction. The detailed reason for this is not clear but is presumed to be as follows.

In a case where a decorative sheet includes a circularly polarized light reflection layer, the visibility of a pattern of the decorative sheet is excellent regardless of observation directions.

Here, the circularly polarized light reflection layer is configured by, for example, a cholesteric liquid crystal layer obtained by immobilizing a cholesteric liquid crystalline phase. In a case where the circularly polarized light reflection layer is visually recognized, the tint of the circularly polarized light reflection layer may change depending on observation directions. In particular, in a case where the circularly polarized light reflection layer is visually recognized from an oblique direction, blue shift derived from the cholesteric liquid crystal layer occurs, and the tint changes as compared to a case where in a case where the circularly polarized light reflection layer is visually recognized from the front direction.

In order to solve the problem, the present inventors found that, by providing the decorative layer where the opening portion is provided on the circularly polarized light reflection layer, a tint change of the decorative sheet depending on observation directions can be suppressed. That is, by providing the opening portion in the decorative layer, the pattern and the color of the circularly polarized light reflection layer can be recognized from the front direction through the opening portion. On the other hand, a range where the circularly polarized light reflection layer can be recognized during observation from an oblique direction is reduced due to the presence of the decorative layer, the pattern derived from the decorative layer is mainly observed, and thus the occurrence of the above-described problem such as blue shift can be suppressed. As a result, it is presumed that the occurrence of a tint change of the decorative sheet depending observation directions can be suppressed.

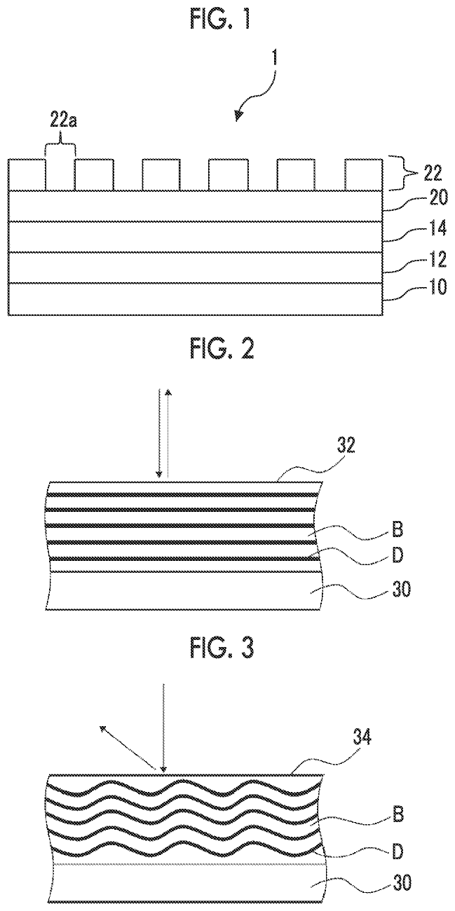

FIG. 1 is a schematic cross-sectional view showing an example of the decorative sheet according to the embodiment of the present invention.

A decorative sheet 1 shown in FIG. 1 includes: a first support 10; an underlayer 12 that is disposed on a surface of the first support 10; a circularly polarized light reflection layer 14 that is disposed on a surface of the underlayer 12; a second support 20 that is disposed on a surface of the circularly polarized light reflection layer 14; and a decorative layer 22 that is disposed on a surface of the second support 20. In addition, a plurality of opening portions 22a are provided in the decorative layer 22.

In the following description, the upper side in the drawing, that is, the decorative layer 22 side will also be referred to as “upper side”, and the lower side in the drawing, that is, the first support 10 side will also be referred to as “lower side”. In addition, the surface of the decorative sheet 1 on the decorative layer 22 side will also be referred to as the visible side, and the surface of the decorative sheet 1 on the first support 10 side will also be referred to as the non-visible side.

[First Support]

The first support 10 is a member that supports the underlayer 12 and the circularly polarized light reflection layer 14.

The first support 10 is not particularly limited, and well-known sheet-shaped materials (film or plate-shaped material) can be used. Examples of the support or the peelable support include a resin film formed of polyester such as polyethylene terephthalate (PET), polycarbonate (PC), an acrylic resin, an epoxy resin, a polyurethane, a cycloolefin resin, a polyamide, a polyolefin, a cellulose derivative, a silicone, or the like. The first support 10 may have a monolayer structure or a multi-layer structure.

The first support 10 is preferably colorless and transparent. The first support 10 being colorless and transparent represents a support that does not substantially have absorption in a visible range. An average transmittance in a wavelength range of 380 to 780 nm is preferably 80% or more and more preferably 90% or more.

The first support 10 may be peelable from the underlayer 12. Alternatively, in a case where the circularly polarized light reflection layer 14 does not include the underlayer 12, the first support 10 may be peelable from the circularly polarized light reflection layer 14.

Examples of the peelable first support 10 include a resin film formed of a resin including a cellulose derivative, a cycloolefin resin, an acrylic resin, or polyethylene terephthalate. In particular, a resin film formed of a resin including polyethylene terephthalate is preferable.

In addition, the peelable first support 10 may be provided by providing a well-known peelable layer between the non-peelable first support 10 and the underlayer 12. Further, by performing a well-known surface treatment on the surface of the non-peelable first support 10, the peelable first support 10 may be obtained.

The peelable first support 10 may be peeled off from the decorative sheet 1, for example, after being bonded to the decorative layer, after being bonded to a constituent member of an image display apparatus to manufacture an image display apparatus, or after being bonded to an interior member of an automobile.

The thickness of the first support 10 is not particularly limited and may be appropriately set to a value that can exhibit the effect as the support depending on the material for forming the first support 10.

The thickness of the first support 10 is preferably 20 μm or more and more preferably 40 μm or more. In addition, the thickness of the peelable first support 10 is preferably 35 μm or more, more preferably 50 μm or more, and still more preferably 80 μm or more. By adjusting the thickness of the first support 10 as the substrate for forming the underlayer 12 and the circularly polarized light reflection layer 14 to be 20 μm or more, in particular, adjusting the thickness of the peelable first support 10 to be 50 μm or more, a layer having no unevenness can be obtained.

The upper limit of the thickness of the first support 10 is not particularly limited, and from the viewpoint of preventing the decorative sheet 1 from being unnecessarily thick, is preferably 1000 μm or less, more preferably 500 μm or less, and still more preferably 300 μm or less.

FIG. 1 shows a case where the decorative sheet 1 includes the first support 10. However, the decorative sheet 1 does not need to include the first support 10.

[Underlayer]

Examples of the underlayer 12 include an alignment film for forming the circularly polarized light reflection layer, a layer functioning as a protective layer that prevents the first support 10 from being damaged by a solvent, and a layer of reducing a difference in surface energy between the formation surface of the circularly polarized light reflection layer 14 and the material (a liquid crystal composition described below) for forming the circularly polarized light reflection layer 14. In addition, in a case where the first support 10 is peelable, the underlayer 12 may function as a protective layer for protecting the circularly polarized light reflection layer 14 after bonding the decorative sheet 1 to another member and peeling the first support 10.

Examples of a material for forming the underlayer 12 include a polyacrylate resin, a polymethacrylate resin, a polyvinyl alcohol resin, a polyolefin resin, a polycarbonate resin, a polyurethane resin, a polystyrene resin, a polyimide resin, an epoxy resin, a polyester resin, and a typical polyether resin. The underlayer 12 may have a monolayer structure or a multi-layer structure.

The thickness of the underlayer 12 is not particularly limited and may be appropriately adjusted to a value that can satisfy required properties depending on the material for forming the underlayer 12. The thickness of the underlayer 12 is preferably 0.01 to 8 μm and more preferably 0.05 to 3

[Circularly Polarized Light Reflection Layer]

The circularly polarized light reflection layer 14 is a layer that reflects circularly polarized light, and is a layer itself that can display a pattern or a color.

It is preferable that the circularly polarized light reflection layer 14 includes a cholesteric liquid crystal layer obtained by immobilizing a cholesteric liquid crystalline phase, and it is more preferable that the circularly polarized light reflection layer 14 consists of a cholesteric liquid crystal layer.

It is known that the cholesteric liquid crystalline phase exhibits selective reflectivity at a specific wavelength.

A central wavelength of selective reflection (selective reflection center wavelength) X, of a general cholesteric liquid crystalline phase depends on a helical pitch P in the cholesteric liquid crystalline phase and satisfies a relationship of λ=n×P with an average refractive index n of the cholesteric liquid crystalline phase. Therefore, the selective reflection center wavelength can be adjusted by adjusting the helical pitch.

The selective reflection center wavelength of the cholesteric liquid crystalline phase increases as the helical pitch increases.

The helical pitch refers to one pitch (helical period) of the helical structure of the cholesteric liquid crystalline phase, in other words, one helical turn. That is, the helical pitch refers to the length in a helical axis direction in which a director of the liquid crystal compound constituting the cholesteric liquid crystalline phase rotates by 360°. For example, in the case of rod-shaped liquid crystal, the director is a major axis direction.

The helical pitch of the cholesteric liquid crystalline phase depends on the kind of the chiral agent used together with the liquid crystal compound and the concentration of the chiral agent added during the formation of the cholesteric liquid crystal layer. Therefore, a desired helical pitch can be obtained by adjusting these conditions.

The details of the adjustment of the pitch can be found in “Fuji Film Research & Development” No. 50 (2005), pp. 60 to 63. As a method of measuring a sense of helix and a helical pitch, a method described in “Introduction to Experimental Liquid Crystal Chemistry”, (the Japanese Liquid Crystal Society, 2007, Sigma Publishing Co., Ltd.), p. 46, and “Liquid Crystal Handbook” (the Editing Committee of Liquid Crystal Handbook, Maruzen Publishing Co., Ltd.), p. 196 can be used.

In addition, the cholesteric liquid crystalline phase exhibits selective reflectivity with respect to left or right circularly polarized light at a specific wavelength. Whether or not the reflected light is right circularly polarized light or left circularly polarized light is determined depending on a helical twisted direction (sense) of the cholesteric liquid crystalline phase. Regarding the selective reflection of the circularly polarized light by the cholesteric liquid crystalline phase, in a case where the helical twisted direction of the cholesteric liquid crystal layer is right, right circularly polarized light is reflected, and in a case where the helical twisted direction of the cholesteric liquid crystal layer is left, left circularly polarized light is reflected.

A direction of rotation of the cholesteric liquid crystalline phase can be adjusted by adjusting the kind of the liquid crystal compound that forms the cholesteric liquid crystal layer and/or the kind of the chiral agent to be added.

Here, in the decorative sheet 1, it is preferable that the circularly polarized light reflection layer 14 has a pitch gradient structure in which a helical pitch changes in a thickness direction. The thickness direction is an up-down direction in FIG. 1. As a result, a plurality of circularly polarized light reflection layers 14 do not need to be provided. Therefore, there are advantageous effects in that the thickness of the decorative sheet 1 can be reduced and the process can be simplified.

In the example shown in the drawing, in the circularly polarized light reflection layer 14, the helical pitch gradually increases upward. That is, in the circularly polarized light reflection layer 14, a selective reflection center wavelength, that is, a wavelength range of light that is selectively reflected gradually increases upward.

In the following description, in the cholesteric liquid crystal layer, the pitch gradient structure in which the helical pitch changes in the thickness direction will also be referred to as “a pitch gradient structure (PG structure)”.

In order to form the cholesteric liquid crystal layer having the PG structure, the chiral agent in which isomerization, dimerization, isomerization, dimerization or the like occurs during light irradiation such that the helical twisting power (HTP) changes is used. By irradiating the liquid crystal composition with light having a wavelength at the HTP of the chiral agent changes before or during the curing of the liquid crystal composition for forming the cholesteric liquid crystal layer, the cholesteric liquid crystal layer having the PG structure can be formed.

For example, by using a chiral agent in which the HTP decreases during light irradiation, the HTP of the chiral agent decreases during light irradiation.

Here, the irradiated light is absorbed by a material for forming the cholesteric liquid crystal layer. Accordingly, for example, in a case where the light is irradiated from the upper side, the irradiation dose of the light gradually decreases from the upper side to the lower side. That is, the amount of decrease in the HTP of the chiral agent gradually decreases from above to below. Therefore, on the upper side where the decrease in HTP is large, the induction of helix is small, and thus the helical pitch is long. On the lower side where the decrease in HTP is small, helix is induced by the original HTP of the chiral agent, and thus the helical pitch decreases.

That is, in this case, in the cholesteric liquid crystal layer, longer wavelength light is selectively reflected from the upper side, and shorter wavelength light is selectively reflected from the lower side. Accordingly, by using the cholesteric liquid crystal layer having the PG structure in which the helical pitch changes in the thickness direction, light in a wide wavelength range can be selectively reflected.

In addition, it is preferable that, in a cross-section of the circularly polarized light reflection layer 14 observed with a scanning electron microscope (SEM), a stripe pattern in which bright portions B (bright lines) and dark portions D (dark lines) derived from a cholesteric liquid crystalline phase are alternately laminated in the thickness direction (the up-down direction in FIG. 1) is observed.

Here, in the decorative sheet 1, it is preferable that, in the cross-section of the circularly polarized light reflection layer 14 observed with a SEM, the bright portions B and the dark portions D have a flapping structure at least a part of which forms periodical flapping unevenness in a plane direction.

That is, it is preferable that the circularly polarized light reflection layer 14 has a cholesteric liquid crystal structure in which an angle between the helical axis and the surface of the reflective layer periodically changes. In other words, it is preferable that the circularly polarized light reflection layer 14 has a cholesteric liquid crystal structure, the cholesteric liquid crystal structure provides a stripe pattern including the bright portions B and the dark portions D in a cross-sectional view of the reflective layer that is observed with a SEM, and an angle between a normal line of a line formed by a dark portion and the surface of the reflective layer periodically changes.

It is preferable that the flapping structure is a structure in which at least one region M where an absolute value of a tilt angle of a continuous line of the bright portions B or the dark portions D that form the stripe pattern with respect to a plane of the cholesteric liquid crystal layer (reflective layer) is 5° or more is present, and a peak or valley having a tilt angle of 0° is specified at two points most adjacent to each other with the region M sandwiched therebetween in a plane direction.

The peak or valley having a tilt angle of 0° may have a protrusion shape or a recessed shape. However, the peak or valley may be a point having a stepwise shape or a rack shape as long as it has a tilt angle of 0°. In the flapping structure, it is preferable that the region M in which an absolute value of a tilt angle of a continuous line of the bright portions B or the dark portions D in the stripe pattern is 5° or more and the peak or valley in which the region M is sandwiched are repeated multiple times.

FIG. 2 conceptually shows a cross-section of a layer obtained by immobilizing a general cholesteric liquid crystalline phase.

As described above, as shown in FIG. 2, in a case where a cross-section of a cholesteric liquid crystal layer 32 formed on a substrate 30 is observed with a SEM, the stripe pattern including the bright portions B and the dark portions D is observed. That is, in the cross-section of the cholesteric liquid crystal layer, a layered structure in which the bright portions B and the dark portions D are alternately laminated in the thickness direction is observed.

In the cholesteric liquid crystal layer, a structure in which the bright portion B and the dark portion D are repeated twice corresponds to the helical pitch. Therefore, the helical pitch of the cholesteric liquid crystal layer, that is, the reflective layer can be measured from a SEM cross-sectional view. That is, the structure in which the bright portion B and the dark portion D are repeated twice includes three bright portions and two dark portions.

In the cholesteric liquid crystal layer 32, in general, the stripe pattern (layered structure) including the bright portions B and the dark portions D is formed parallel to the surface of the substrate 30 as shown in FIG. 2. The cholesteric liquid crystal layer 32 exhibits specular reflectivity. That is, in a case where light is incident from the normal direction of the cholesteric liquid crystal layer 32, the light is reflected from the normal direction. The light is not likely to be reflected in the oblique direction, and diffuse reflectivity is poor (refer to arrows in FIG. 2).

On the other hand, in a case where the bright portions B and the dark portions D have the flapping structure (undulated structure) as in the cholesteric liquid crystal layer 34 of which the cross-section is conceptually shown in FIG. 3 and light is incident from the normal direction of the cholesteric liquid crystal layer 34, a region where the helical axis of the liquid crystal compound is tilted as conceptually shown in FIG. 3. Therefore, a part of the incidence light is reflected in the oblique direction (refer to arrows in FIG. 3).

That is, in the cholesteric liquid crystal layer obtained by immobilizing a cholesteric liquid crystalline phase, the bright portions B and the dark portions D have the flapping structure. As a result, a reflective layer having high diffuse reflectivity can be realized.

It is preferable that, in the cross-section of the circularly polarized light reflection layer 14 observed with a SEM, the bright portions B and the dark portions D derived from a cholesteric liquid crystalline phase have the flapping structure.

In the following description, the configuration in which the bright portions B and the dark portions D derived from a cholesteric liquid crystalline phase have the flapping structure in the cross-section of the cholesteric liquid crystal layer (circularly polarized light reflection layer) observed with a SEM will also be simply referred to as “the cholesteric liquid crystal layer (circularly polarized light reflection layer) has the flapping structure”.

The cholesteric liquid crystal layer having the flapping structure can be formed by forming the cholesteric liquid crystal layer on a formation surface on which an alignment treatment such as rubbing is not performed. Accordingly, in the example shown in the drawing, the circularly polarized light reflection layer 14 having the flapping structure can be formed by forming the circularly polarized light reflection layer 14 on the underlayer 12 without performing the alignment treatment such as the rubbing treatment.

That is, in a case where the circularly polarized light reflection layer 14 as the cholesteric liquid crystal layer is formed on the underlayer 12 on which the alignment treatment is not performed, there is no horizontal alignment restriction force with respect to the liquid crystal compound, and thus the alignment direction of the liquid crystal compound on the surface of the underlayer 12 varies depending on physical properties of the underlayer 12. In a case where the circularly polarized light reflection layer 14 is formed in this state, the helical axis of the liquid crystal compound forming the cholesteric liquid crystalline phase faces various directions. As a result, in the circularly polarized light reflection layer 14, the stripe pattern including the bright portions B and the dark portions D have the flapping structure.

In the decorative sheet 1, the bright portions B and the dark portions D of the circularly polarized light reflection layer 14 are not limited to a configuration in which the entire area of all the bright portions B and the dark portions D have the flapping structure, and at least a part of the bright portions B and the dark portions D only needs to have the flapping structure. That is, in the decorative sheet 1, the bright portions B and the dark portions D in the circularly polarized light reflection layer 14 may include a region not having the flapping structure due to the formation of a defect portion or the like.

As described above, in order to obtain excellent diffuse reflectivity, it is preferable that, in the cross-section of the cholesteric liquid crystal layer (circularly polarized light reflection layer 14) observed with a SEM, the bright portions B and the dark portions D derived from a cholesteric liquid crystalline phase have the flapping structure. In addition, in order to widen the selective reflection wavelength range, it is preferable that the PG structure in which the helical pitch changes in the thickness direction of the cholesteric liquid crystal layer (circularly polarized light reflection layer 14) is provided.

Here, as described above, for example, the PG structure can be obtained by using a chiral agent of which the HTP changes by light irradiation and irradiating the chiral agent with light having a wavelength that is absorbed by the chiral agent during the formation of the cholesteric liquid crystal layer such that the irradiation dose of light in the thickness direction, that is, the amount of change in HTP changes. Accordingly, as a difference in the irradiation dose of the light during the formation of the cholesteric liquid crystal layer increases in the thickness direction, the selective reflection wavelength range can be widened.

The thickness of the circularly polarized light reflection layer 14 is not particularly limited and is preferably 0.2 to 20 μm, more preferably 0.5 to 14 μm, and still more preferably 1.0 to 10 μm.

In the circularly polarized light reflection layer 14, the peak-to-peak distance and the amplitude (the height of undulation) of the flapping structure are also not particularly limited.

Here, in the cholesteric liquid crystal layer (circularly polarized light reflection layer 14) having the flapping structure, as the peak-to-peak distance decreases, higher diffuse reflectivity is exhibited. In addition, as the amplitude increases, higher diffuse reflectivity is exhibited.

From the viewpoints of forming the flapping structure having a small number of defects and obtaining higher diffuse reflectivity, the average value of peak-to-peak distances in the flapping structure of the circularly polarized light reflection layer 14 is preferably 0.5 to 50 μm, more preferably 1.5 to 30 μm, and still more preferably 2.5 to 20 μm.

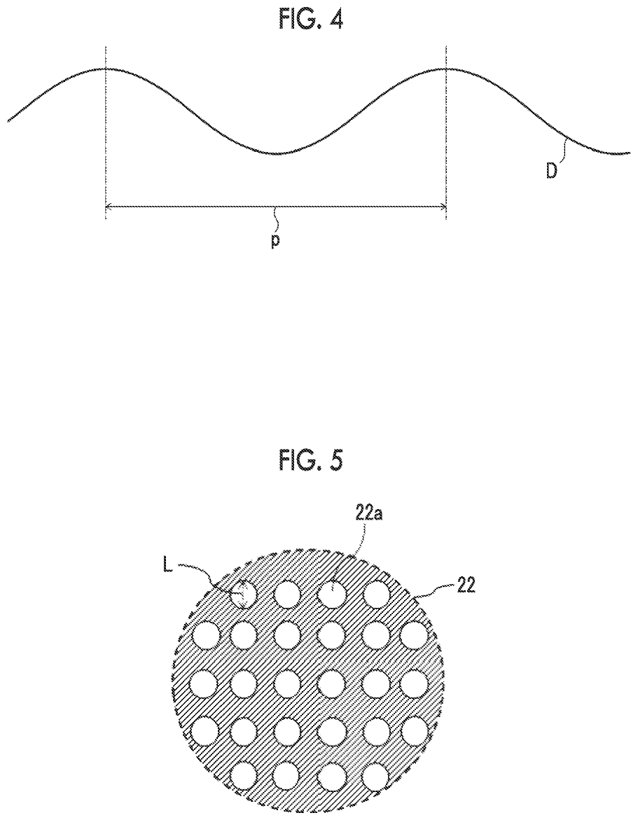

The peak-to-peak distance of the flapping structure refers to a distance p between peaks of convex portions most adjacent to each other in the flapping structure as conceptually shown in FIG. 4.

Specifically, the average value of the peak-to-peak distance is measured as follows. First, the distance in the plane direction of the cholesteric liquid crystal layer (circularly polarized light reflection layer 14) between peaks (or valleys) having a tilt angle of 0° at two points that are most adjacent to each other with respect to a region M where the absolute value of an inclination angle with respect to a plane of the cholesteric liquid crystal layer (circularly polarized light reflection layer 14) is 5° or more is measured. By performing this measurement is performed on the length of 100 μm of the cholesteric liquid crystal layer (circularly polarized light reflection layer 14) in the cross-sectional major axis direction, the arithmetic mean value of all the film thicknesses is obtained as the average value of the peak-to-peak distances.

In the decorative sheet 1, a wavelength range where the circularly polarized light reflection layer 14 selectively reflects light is not particularly limited and may be appropriately adjusted depending on the use or the like of the decorative sheet 1. It is preferable that the wavelength range is in a visible range.

In the present specification, unless specified otherwise, the visible range refers to a wavelength range of 380 to 780 nm.

In the decorative sheet 1, in order to form the circularly polarized light reflection layer 14, light irradiation for curing the circularly polarized light reflection layer 14 may be performed after performing light irradiation for changing the HTP of the chiral agent. Alternatively, light irradiation for changing the HTP of the chiral agent and light irradiation for curing the circularly polarized light reflection layer 14 may be performed at the same time.

The HTP of the chiral agent is likely to decrease by light irradiation. Therefore, it is preferable that the helical pitch in the thickness direction of the circularly polarized light reflection layer 14 is long on the side where the curing rate is high and is short on the side where the curing rate is low.

The example of FIG. 1 shows a case where the circularly polarized light reflection layer 14 is a monolayer structure. However, the present invention is not limited to this example, and the circularly polarized light reflection layer 14 may have a multi-layer structure.

The circularly polarized light reflection layer 14 may be formed to have the same properties over the entire surface or may be formed to have a plurality of regions having different physical properties (for example, peak wavelengths of reflection) in an in-plane direction (for example, the circularly polarized light reflection layer 14 has a patterned shape).

Examples of a method of forming the circularly polarized light reflection layer 14 having a patterned shape include a method of applying a cholesteric liquid crystal using a mask (the masked portion is a portion to which the cholesteric liquid crystal is not applied), a method of adjusting the uniformly applied cholesteric liquid crystal to form a partially isotropic layer using a temperature or the like, and a method of applying a cholesteric liquid crystal using an ink jet method. In addition, for example, a method changing photoisomerization of a chiral agent for performing ultraviolet irradiation or the like for each of regions, a method of changing a distribution of a chiral agent in a plane, and a method of changing a stretching ratio in a plane can be used.

In the circularly polarized light reflection layer 14, a maximum value of an integral reflectivity excluding a specular reflection component in a wavelength range of 380 to 780 nm is preferably 0% or more, more preferably 7% or more, still more preferably 12% or more, and still more preferably 20% or more. By adjusting the maximum value of the integral reflectivity to be 7% or more, the decorative sheet 1 having excellent visibility of a pattern and having a small tint change depending on observation directions can be obtained.

In an aspect where the decorative sheet 1 is combined with a circularly polarizing plate or an aspect where the decorative sheet 1 is disposed on a display element, from the viewpoint of allowing transmission of only circularly polarized light on a single side, an upper limit of the maximum value of the integral reflectivity is preferably 60% or less and more preferably 50% or less.

The maximum value of the integral reflectivity of the circularly polarized light reflection layer 14 excluding a specular reflection component can be adjusted to be in the above-described range by appropriately adjusting, for example, the film thickness during the formation of the circularly polarized light reflection layer 14, the bandwidth in the reflection spectrum, and the like.

The maximum value of the integral reflectivity of the circularly polarized light reflection layer 14 excluding a specular reflection component can be measured using a method described below in Examples.

<Liquid Crystal Composition>

It is preferable that the circularly polarized light reflection layer 14 (cholesteric liquid crystal layer) is formed of a liquid crystal composition including a liquid crystal compound and a chiral agent.

(Liquid Crystal Compound)

It is preferable that the liquid crystal compound used for forming the cholesteric liquid crystal layer has two or more polymerizable groups. That is, a polymerizable liquid crystal compound is preferable. In addition, an average molar absorption coefficient in 300 to 400 nm is preferably less than 5000. On the other hand, in an aspect where the cholesteric liquid crystal layer and the decorative sheet including the cholesteric liquid crystal layer are stretched, it is preferable that the liquid crystal compound used for forming the cholesteric liquid crystal layer includes at least one liquid crystal compound having one polymerizable group.

The liquid crystal compound may be a rod-like liquid crystal compound or a disk-like liquid crystal compound and is preferably a rod-like liquid crystal compound.

Examples of the rod-like liquid crystal compound for forming a cholesteric liquid crystal structure include a rod-like nematic liquid crystal compound. As the rod-like nematic liquid crystal compound, an azomethine compound, an azoxy compound, a cyanobiphenyl compound, a cyanophenyl ester compound, a benzoate compound, a phenyl cyclohexanecarboxylate compound, a cyanophenylcyclohexane compound, a cyano-substituted phenylpyrimidine compound, an alkoxy-substituted phenylpyrimidine compound, a phenyldioxane compound, a tolan compound, or an alkenylcyclohexylbenzonitrile compound is preferably used. Not only a low-molecular-weight liquid crystal compound but also a polymer liquid crystal compound can be used.

Examples of the polymerizable group include an unsaturated polymerizable group, an epoxy group, and an aziridinyl group. Among these, an unsaturated polymerizable group is preferable, and an ethylenically unsaturated polymerizable group is more preferable. The polymerizable group can be introduced into the molecules of the liquid crystal compound using various methods. The number of polymerizable groups in the liquid crystal compound is preferably 1 to 6 and more preferably 1 to 3 in one molecule.

Examples of the liquid crystal compound include compounds described in Makromol. Chem. (1989), Vol. 190, p. 2255, Advanced Materials (1993), Vol. 5, p. 107, U.S. Pat. Nos. 4,683,327A, 5,622,648A, 5,770,107A, WO1995/22586A, WO1995/24455A, WO1997/00600A, WO1998/23580A, WO1998/52905A, WO2016/194327A, WO2016/052367A, JP1989-272551A (JP-H1-272551A), JP1994-16616A (JP-H6-16616A), JP1995-110469A (JP-H7-110469A), JP1999-80081A (JP-H11-80081A), and JP2001-328973A.

In the liquid crystal composition, that is, the cholesteric liquid crystal layer, two or more liquid crystal compounds may be used in combination. In a case where two or more liquid crystal compounds are used in combination, there may be a case where the alignment temperature can be decreased.

In addition, the addition amount of the liquid crystal compound in the liquid crystal composition is not particularly limited and is preferably 80 to 99.9 mass %, more preferably 85 to 99.5 mass %, and still more preferably 90 to 99 mass % with respect to the solid content mass (mass excluding a solvent) of the liquid crystal composition.

(Chiral Agent: Optically Active Compound)

As the chiral agent used for forming the cholesteric liquid crystal layer, any well-known chiral agents can be used as long as the HTP thereof changes by light irradiation. A chiral agent having a molar absorption coefficient of 30000 or higher at a wavelength of 313 to 365 nm is preferably used.

The chiral agent has a function of causing a helical structure of a cholesteric liquid crystalline phase to be formed. The chiral agent may be selected depending on the purpose because a sense of helix or a helical pitch induced from the compound varies.

As the chiral agent, a well-known compound can be used, but a compound having a cinnamoyl group is preferable. Examples of the chiral agent include compounds described in Liquid Crystal Device Handbook (No. 142 Committee of Japan Society for the Promotion of Science, 1989), Chapter 3, Article 4-3, chiral agent for TN or STN, p. 199), JP2003-287623A, JP2002-302487A, JP2002-80478A, JP2002-80851A, JP2010-181852A, and JP2014-034581A.

In general, the chiral agent includes an asymmetric carbon atom. However, an axially asymmetric compound or a planar asymmetric compound not having an asymmetric carbon atom can be used as the chiral agent. Examples of the axially asymmetric compound or the planar asymmetric compound include binaphthyl, helicene, paracyclophane, and derivatives thereof. The chiral agent may include a polymerizable group.

In a case where both the chiral agent and the liquid crystal compound have a polymerizable group, a polymer which includes a repeating unit derived from the polymerizable liquid crystal compound and a repeating unit derived from the chiral agent can be formed due to a polymerization reaction of a polymerizable chiral agent and the polymerizable liquid crystal compound. In this aspect, it is preferable that the polymerizable group in the polymerizable chiral agent is the same as the polymerizable group included in the polymerizable liquid crystal compound. Accordingly, the polymerizable group of the chiral agent is preferably an unsaturated polymerizable group, an epoxy group, or an aziridinyl group, more preferably an unsaturated polymerizable group, and still more preferably an ethylenically unsaturated polymerizable group.

In addition, the chiral agent may be a liquid crystal compound.

As the chiral agent, an isosorbide derivative, an isomannide derivative, or a binaphthyl derivative can be preferably used. As the isosorbide derivative, a commercially available product such as LC-756 (manufactured by BASF SE) may be used.

The content of the chiral agent in the liquid crystal composition is preferably 0.01 to 200 mol % and more preferably 1 to 30 mol % with respect to the amount of the liquid crystal compound.

(Polymerization Initiator)

It is preferable that the liquid crystal composition includes a polymerization initiator. In an aspect where a polymerization reaction progresses with ultraviolet irradiation, it is preferable that the polymerization initiator is a photopolymerization initiator which initiates a polymerization reaction with ultraviolet irradiation.

Examples of the photopolymerization initiator include an α-carbonyl compound (described in US2367661A and US2367670A), an acyloin ether (described in US2448828A), an α-hydrocarbon-substituted aromatic acyloin compound (described in U.S. Pat. No. 2,722,512A), a polynuclear quinone compound (described in U.S. Pat. No. 3,046,127A and US2951758A), a combination of a triarylimidazole dimer and p-aminophenyl ketone (described in US3549367A), an acridine compound and a phenazine compound (described in JP1985-105667A (JP-560-105667A) and US4239850A), an acylphosphine oxide compound (described in JP1988-040799B (JP-563-040799B), JP1993-029234B (JP-H5-029234B), JP1998-095788A (JP-H10-095788A), JP1998-29997A (JP-H10-29997A), JP2001-233842A, JP2000-080068A, JP2006-342166A, JP2013-114249A, JP2014-137466A, JP4223071B, JP2010-262028A, and JP2014-500852A), an oxime compound (described in JP2000-066385A and Japanese Patent No. 4454067), and an oxadiazole compound (described in US4212970A). The details of the polymerization initiator can also be found in, for example, the description of paragraphs “0500” to “0547” of JP2012-208494A.

Examples of the polymerization initiator that can be used include an acylphosphine oxide compound and an oxime compound.

As the acylphosphine oxide compound, for example, IRGACURE 810 (manufactured by BASF SE, compound name: bis(2,4,6-trimethylbenzoyl)-phenylphosphine oxide) as a commercially available product can be used. As the oxime compound, for example, a commercially available product such as IRGACURE OXE01 (manufactured by BASF SE), IRGACURE OXE02 (manufactured by BASF SE), TR-PBG-304 (manufactured by Changzhou Tronly New Electronic Materials Co., Ltd.), ADEKA ARKLS NCI-831 and ADEKA ARKLS NCI-930 (manufactured by Adeka Corporation), ADEKA ARKLS NCI-831 (manufactured by Adeka Corporation) can be used.

The polymerization initiators may be used alone or in combination of two or more kinds.

In a case where light irradiation for curing the circularly polarized light reflection layer 14 (cholesteric liquid crystal layer) is performed to form the reflective layer after performing light irradiation for changing the HTP of the chiral agent, it is preferable to use a photopolymerization initiator that inhibits polymerization during the light irradiation for changing the HTP of the chiral agent. In this case, the content of the photopolymerization initiator in the liquid crystal composition is preferably 0.05 to 3 mass % and more preferably 0.3 to 1.5 mass % with respect to the content of the liquid crystal compound. In addition, the light irradiation for changing the HTP of the chiral agent and the light irradiation for curing the reflective layer are performed at the same time, the content of the photopolymerization initiator in the liquid crystal composition is preferably 0.01 to 0.3 mass % and more preferably 0.01 to 0.2 mass % with respect to the content of the liquid crystal compound.

(Crosslinking Agent)

In order to improve the film hardness after curing and to improve durability, the liquid crystal composition may optionally include a crosslinking agent. As the crosslinking agent, a curing agent which can perform curing with ultraviolet light, heat, moisture, or the like can be suitably used.

The kind of the crosslinking agent is not particularly limited and can be appropriately selected depending on the purpose. Examples of the crosslinking agent include: a polyfunctional acrylate compound such as trimethylol propane tri(meth)acrylate or pentaerythritol tri(meth)acrylate; an epoxy compound such as glycidyl (meth)acrylate or ethylene glycol diglycidyl ether; an aziridine compound such as 2,2-bis hydroxymethyl butanol-tris [3-(1-aziridinyl)propionate] or 4,4-bis(ethyleneiminocarbonylamino)diphenylmethane; an isocyanate compound such as hexamethylene diisocyanate or a biuret type isocyanate; a polyoxazoline compound having an oxazoline group at a side chain thereof; and an alkoxysilane compound such as vinyl trimethoxysilane or N-(2-aminoethyl)-3-aminopropyltrimethoxysilane.

In addition, depending on the reactivity of the crosslinking agent, a well-known catalyst can be used, and not only film hardness and durability but also productivity can be improved. The catalysts may be used alone or in combination of two or more kinds.

The content of the crosslinking agent in the liquid crystal composition is preferably 3% to 20 mass % and more preferably 5% to 15 mass % with respect to the solid content of the liquid crystal composition.

(Alignment Control Agent)

An alignment control agent contributing to the stable or rapid formation of a cholesteric liquid crystal structure with planar alignment may be added to the liquid crystal composition.

Examples of the alignment control agent include fluorine (meth)acrylate polymers described in paragraphs “0018” to “0043” of JP2007-272185A, and compounds represented by Formulae (I) to (IV) described in paragraphs “0031” to “0034” of JP2012-203237A.

The alignment control agents may be used alone or in combination of two or more kinds.

The addition amount of the alignment control agent in the liquid crystal composition is preferably 0.01 to 10 mass %, more preferably 0.01 to 5 mass %, and still more preferably 0.02 to 1 mass % with respect to the total mass of the liquid crystal compound.

(Surfactant)

The liquid crystal composition may include a surfactant.

It is preferable that the surfactant is a compound which can function as an alignment control agent contributing to the stable or rapid formation of a cholesteric structure with planar alignment. Examples of the surfactant include a silicone-based surfactant and a fluorine-based surfactant. Among these, a fluorine-based surfactant is preferable.

Specific examples of the surfactant include compounds described in paragraphs “0082” to “0090” of JP2014-119605A, compounds described in paragraphs “0031” to “0034” of JP2012-203237A, exemplary compounds described in paragraphs “0092” and “0093” of JP2005-099248A, exemplary compounds described in paragraphs “0076” to “0078” and paragraphs “0082” to “0085” of JP2002-129162A, and fluorine (meth)acrylate polymers described in paragraphs “0018” to “0043” of JP2007-272185A.

The horizontal alignment agents may be used alone or in combination of two or more kinds.

As the fluorine-based surfactant, a compound represented by the following Formula (I) described in paragraphs “0082” to “0090” of JP2014-119605A is more preferable.

(Hb¹¹-Sp¹¹-L¹¹-Sp¹²-L¹²)ₘ₁₁-A¹¹-L¹³-T¹¹-L¹⁴-A¹²-(L¹⁵-Sp¹³-L¹⁶-Sp¹⁴-Hb¹¹)ₙ₁₁ Formula (I)

In Formula (I), L¹¹, L¹², L¹³, L¹⁴, L¹⁵ and L¹⁶ each independently represent a single bond, —O—, —S—, —CO—, —COO—, —OCO—, —COS—, —SCO—, —NRCO—, or —CONR— (in Formula (I), R represents a hydrogen atom or an alkyl group having 1 to 6 carbon atoms). —NRCO— or —CONR— has an effect of reducing solubility and is likely to increase haze during the preparation of dots. Therefore, —O—, —S—, —CO—, —COO—, —OCO—, —COS— or —SCO— is preferable, and from the viewpoint of the stability of the compound, —O—, —CO—, —COO—, or —OCO— is more preferable. An alkyl group represented by R may be linear or branched. An alkyl group having 1 to 3 carbon atoms is more preferable, and examples thereof include a methyl group, an ethyl group, and an n-propyl group.

Sp¹¹, Sp¹², Sp¹³, and Sp¹⁴ each independently represent a single bond or an alkylene group having 1 to 10 carbon atoms, more preferably a single bond or an alkylene group having 1 to 7 carbon atoms, and still more preferably a single bond or an alkylene group having 1 to 4 carbon atoms. Note that a hydrogen atom in the alkylene group may be substituted with a fluorine atom. The alkylene group may have a branch or not, and a linear alkylene group having no branch is preferable. From the viewpoint of synthesis, it is preferable that Sp¹¹ and Sp¹⁴ are the same and Sp¹² and Sp¹³ are the same.

A¹¹ and A¹² represent a monovalent to tetravalent aromatic hydrocarbon group. The number of carbon atoms in the aromatic hydrocarbon group is preferably 6 to 22, more preferably 6 to 14, still more preferably 6 to 10, and still more preferably 6. The aromatic hydrocarbon group represented by A¹¹ and A₁₂ may have a substituent. Examples of the substituent include an alkyl group having 1 to 8 carbon atoms, an alkoxy group, a halogen atom, a cyano group, and an ester group. The description and preferable ranges of the groups can be found in the corresponding description of T¹¹ described below. Examples of a substituent with which the aromatic hydrocarbon group represented by A¹¹ or A¹² is substituted include a methyl group, an ethyl group, a methoxy group, an ethoxy group, a bromine atom, a chlorine atom, and a cyano group. A molecule including a large amount of a perfluoroalkyl portion can cause liquid crystal to be aligned even in a small addition amount, which leads to reduction in haze. Therefore, in order for the molecule to include many perfluoroalkyl groups, it is preferable that A¹¹ and A¹² are tetravalent. From the viewpoint of synthesis, it is preferable that A¹¹ and A¹² are the same.

It is preferable that T¹¹ represents a divalent group or a divalent aromatic heterocyclic group preferably represented by any one of the following formulae (X in T¹¹ represents an alkyl group having 1 to 8 carbon atoms, an alkoxy group, a halogen atom, a cyano group, or an ester group, and Ya, Yb, Yc, and Yd each independently represent a hydrogen atom or an alkyl group having 1 to 4 carbon atoms).

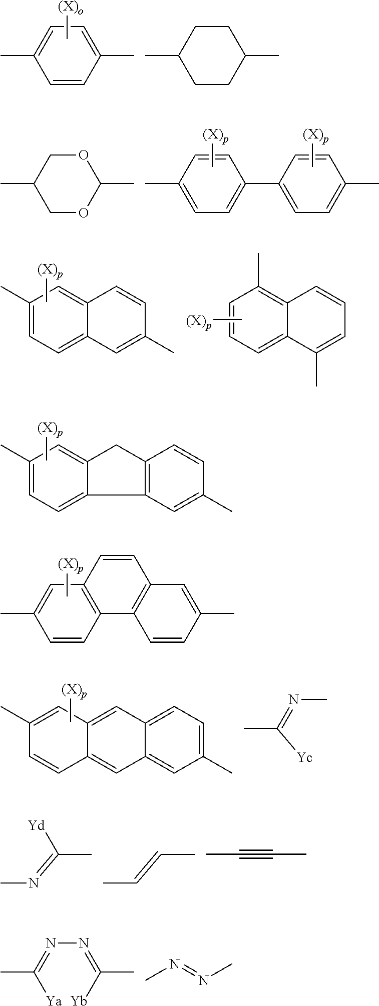

In particular, the following group is more preferable.

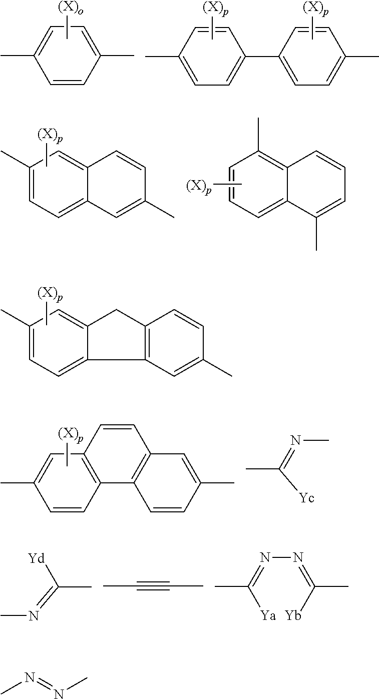

The following group is still more preferable.

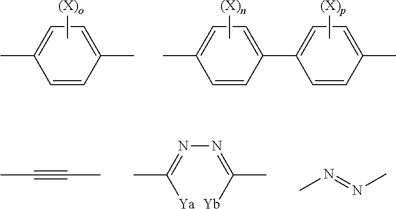

The following group is most preferable.

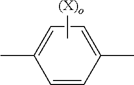

The number of carbon atoms that can be included in the alkyl group represented by X in T¹¹ is 1 to 8, preferably 1 to 5, and more preferably 1 to 3. The alkyl group may be linear, branched, or cyclic and is preferably linear or branched. Preferable examples of the alkyl group include a methyl group, an ethyl group, an n-propyl group, and an isopropyl group. Among these, a methyl group is preferable.

The details of an alkyl portion of the alkoxy group represented by X in T¹¹ can be found in the description and preferable range of the alkyl group represented by X in T¹¹. Examples of the halogen atom represented by X in T¹¹ include a fluorine atom, a chlorine atom, a bromine atom, and an iodine atom. Among these, a chlorine atom or a bromine atom is preferable. Examples of the ester group represented by X in T¹¹ include a group represented by R^{a}COO—. R^{a} represents, for example, an alkyl group having 1 to 8 carbon atoms. The description and preferable range of the alkyl group represented by R^{a} can be found in the description and preferable range of the alkyl group represented by X in T¹¹. Specific examples of the ester include CH₃COO— and C₂H₅ COO—. The alkyl group having 1 to 4 carbon atoms represented by Ya, Yb, Yc, and Yd may be linear or branched. Examples of the alkyl group having 1 to 4 carbon atoms include a methyl group, an ethyl group, an n-propyl group, and an isopropyl group.

It is preferable that the divalent aromatic heterocyclic group has a 5-membered, 6-membered, or 7-membered heterocyclic ring. A 5- or 6-membered ring is more preferable, and a 6-membered ring is most preferable. As a heteroatom constituting the heterocyclic ring, a nitrogen atom, an oxygen atom, or a sulfur atom is preferable. It is preferable that the heterocyclic ring is an aromatic heterocyclic ring. In general, the aromatic heterocyclic ring is an unsaturated heterocyclic ring. An unsaturated heterocyclic ring having most double bonds is more preferable. Examples of the heterocyclic ring include a furan ring, a thiophene ring, a pyrrole ring, a pyrroline ring, a pyrrolidine ring, an oxazole ring, an isoxazole ring, a thiazole ring, an isothiazole ring, an imidazole ring, an imidazoline ring, an imidazolidine ring, a pyrazole ring, a pyrazoline ring, a pyrazolidine ring, a triazole ring, a furazan ring, a tetrazole ring, a pyran ring, a thiin ring, a pyridine ring, a piperidine ring, an oxazine ring, a morpholine ring, a thiazine ring, a pyridazine ring, a pyrimidine ring, a pyrazine ring, a piperazine ring, and a triazine ring. The divalent heterocyclic group may have a substituent. The description and preferable range of the substituent can be found in the description of the substituent with which the monovalent to tetravalent aromatic hydrocarbon represented by A¹¹ or A¹² is substituted.

Hb¹¹ represents a perfluoroalkyl group having 2 to 30 carbon atoms, more preferably a perfluoroalkyl group having 3 to 20 carbon atoms, and still more preferably a perfluoroalkyl group having 3 to 10 carbon atoms. The perfluoroalkyl group may be linear, branched, or cyclic and is preferably linear or branched and more preferably linear.

m11 and n11 each independently represent 0 to 3 and m11+n11≥1. In this case, a plurality of structures in parentheses may be the same as or different from each other and is preferably the same as each other. m11 and n11 in Formula (I) are determined depending on the valences of A¹¹ and A¹², and preferable ranges thereof are determined depending on the preferable ranges of the valences of A¹¹ and A¹².

o and pin T¹¹ each independently represent an integer of 0 or more. In a case where o and p represent an integer of 2 or more, a plurality of X's may be the same as or different from each other. o in T¹¹ represents preferably 1 or 2. p in T¹¹ represents preferably an integer of 1 to 4 and more preferably 1 to 2.

A molecular structure of the compound represented by Formula (I) may be symmetrical or asymmetrical. “Symmetry” described herein represents at least one of point symmetry, line symmetry, or rotational symmetry, and “asymmetry” described herein does not represent any one of point symmetry, line symmetry, or rotational symmetry.

The compound represented by Formula (I) is a combination of the perfluoroalkyl group (Hb¹¹), the linking groups +Sp¹¹-L¹¹-Sp¹²-L¹²)m11-A¹¹-L¹³- and -L¹⁴-A¹²-(L¹⁵-Sp¹³-L¹⁶-Sp¹⁴)n11- and preferably the divalent group having an excluded volume effect which is represented by T¹¹. Two perfluoroalkyl groups (Hb¹¹) present in the molecule are preferably the same as each other, and the linking groups (Sp¹¹-L¹¹-Sp¹²-L¹²)m11-A¹¹-L¹³ and -L¹⁴-A¹²-(L¹⁵-Sp¹³-L¹³-L¹⁶-Sp¹⁴)n11-present in the molecule are also preferably the same as each other. Hb¹¹-Sp¹¹-L¹²- and -Sp¹³-L¹⁶-Sp¹⁴-Hb¹¹ present at the terminal are preferably a group represented by any one of the following formulae.

(CₐF₂ₐ₊₁)—(C_{b}H_{2b})—(CₐF₂ₐ₊₁)—(C_{b}H_{2b})—O—(CᵣH₂ᵣ)—(CₐF₂ₐ₊₁)—(C_{b}H_{2b})—COO—(CᵣH₂ᵣ)—, and (CₐF₂ₐ₊₁)—(C_{b}H_{2b})—OCO—(CᵣH₂ᵣ)—

In the above formulae, a represents preferably 2 to 30, more preferably 3 to 20, and still more preferably 3 to 10. b represents preferably 0 to 20, more preferably 0 to 10, and still more preferably 0 to 5. a+b represents 3 to 30. r represents preferably 1 to 10 and more preferably 1 to 4.

In addition, Hb¹¹-Sp¹¹-L¹¹-Sp¹²-L¹²- and -L¹⁵-Sp¹³-L¹⁶-Sp¹⁴-Hb¹¹ present at the terminal of Formula (I) are preferably a group represented by any one of the following formulae.

(CₐF₂ₐ₊₁)—(C_{b}H_{2b})—O—(CₐF₂ₐ₊₁)—(C_{b}H_{2b})—COO—,(CₐF₂ₐ₊₁)—(C_{b}H_{2b})—O—(CᵣH₂ᵣ)—O—,(CₐF₂ₐ₊₁)—(C_{b}H_{2b})—COO—(CᵣH₂ᵣ)—COO—, and(CₐF₂ₐ₊₁)—(C_{b}H_{2b})—OCO—(CᵣH₂ᵣ)—COO—.

In the above formulae, a, b, and r have the same definitions as described above.

The addition amount of the surfactant in the liquid crystal composition is preferably to 10 mass %, more preferably 0.01 to 5 mass %, and still more preferably 0.02 to 1 mass % with respect to the total mass of the liquid crystal compound.

(Other Additives)

In addition, the liquid crystal composition may include at least one selected from various additives such as a polymerizable monomer. In addition, optionally, a polymerization inhibitor, an antioxidant, an ultraviolet absorber, a light stabilizer, a coloring material, metal oxide fine particles or the like can be added to the liquid crystal composition in a range where optical performance does not deteriorate.

(Solvent)

The solvent used for preparing the liquid crystal composition is not particularly limited and may be appropriately selected depending on the liquid crystal compound to be added to the composition and the like.

As a solvent, an organic solvent is preferably used. The organic solvent is not particularly limited and can be appropriately selected depending on the liquid crystal compound to be added to the composition and the like. Examples of the organic solvent include a ketone, an alkyl halide, an amide, a sulfoxide, a heterocyclic compound, a hydrocarbon, an ester, and an ether. Among these, a ketone is more preferable in consideration of an environmental burden.

These solvents may be used alone or in combination of two or more kinds.

<Formation of Circularly Polarized Light Reflection Layer>

The circularly polarized light reflection layer 14 (cholesteric liquid crystal layer) can be formed, for example, by dissolving the liquid crystal compound, the chiral agent, and the polymerization initiator and further the optionally added surfactant or the like in a solvent to prepare a liquid crystal composition, applying the liquid crystal composition to the underlayer 12, drying the liquid crystal composition to obtain a coating film, and irradiating the coating film with an actinic ray to cure the liquid crystal composition. As a result, the circularly polarized light reflection layer 14 having a cholesteric liquid crystal structure in which cholesteric regularity is immobilized can be formed.

By applying the liquid crystal composition to the underlayer 12 to form the circularly polarized light reflection layer 14 without performing an alignment treatment such as rubbing on the underlayer 12, the circularly polarized light reflection layer 14 having the flapping structure can be formed as described above. In addition, by performing light irradiation for changing the HTP of the chiral agent before or during the curing of the liquid crystal composition, the circularly polarized light reflection layer 14 having the patterned shape or the PG structure in a plane can also be formed as described above.

(Application and Alignment)

A method of applying the liquid crystal composition is not particularly limited and may be appropriately selected depending on properties of the coating composition, the materials for forming the underlayer 12 and the support 10, and the like.

Examples of the method of applying the liquid crystal composition include a wire bar coating method, a curtain coating method, an extrusion coating method, a direct gravure coating method, a reverse gravure coating method, a die coating method, a spin coating method, a dip coating method, a spray coating method, and a slide coating method.

In addition, the liquid crystal composition may be applied to the underlayer 12 by transferring the liquid crystal composition that is separately applied to the support. In addition, the liquid crystal composition can also be jetted. Examples of the jetting method include an ink jet method.

By heating the applied liquid crystal composition, liquid crystal molecules are aligned. The heating temperature is preferably 200° C. or lower and more preferably 130° C. or lower. Through the alignment treatment, a structure in which the liquid crystal compound is twisted and aligned to have a helical axis can be obtained.

(Curing of Liquid Crystal Composition)

Next, by polymerizing the aligned liquid crystal compound, the liquid crystal composition can be cured to form the circularly polarized light reflection layer (cholesteric liquid crystal layer). Regarding the polymerization of the polyfunctional liquid crystal compound, thermal polymerization or photopolymerization may be performed, and photopolymerization is preferable.

It is preferable that light irradiation for curing the liquid crystal composition is performed by ultraviolet irradiation. The illuminance of ultraviolet light is preferably 15 to 1500 mW/cm² and more preferably 100 to 600 mW/cm². In addition, the irradiation energy of ultraviolet light is preferably 20 mJ/cm² to 50 J/cm² and more preferably 100 to 1500 mJ/cm².

A wavelength of ultraviolet light to be irradiated may be appropriately selected depending on the liquid crystal compound in the liquid crystal composition and the like. In order to cure the liquid crystal composition, a light source having an emission wavelength of 200 to 430 nm is preferable, and a light source having an emission wavelength of 300 to 430 nm is more preferable. In addition, during ultraviolet irradiation, from the viewpoint of preventing a decomposition, side reaction, or the like of a material to be used, for example, a short wavelength cut filter may be used to suppress the transmittance of light having a wavelength of 300 nm or shorter to be 20% or less.

In a case where the cholesteric liquid crystal layer having the patterned shape or the PG structure in a plane is formed, light irradiation for changing the HTP of the chiral agent is performed before the curing of the liquid crystal composition. Alternatively, in a case where the cholesteric liquid crystal layer having the patterned shape or the PG structure in a plane is formed, light irradiation for changing the HTP of the chiral agent and light irradiation for curing the liquid crystal composition may be performed at the same time. The light for changing the HTP of the chiral agent may be appropriately selected depending on properties of the chiral agent. For example, in a case where a light source having an emission wavelength of 200 to 430 nm is used, light having a wavelength that is appropriate for inducing a change in the HTP of the chiral agent can be irradiated by using a band pass filter or the like. In addition, an exposure mask may also be used depending on the in-plane patterned shape in order to control the irradiation dose of the light for changing the HTP of the chiral agent.

In a case where the circularly polarized light reflection layer 14 is formed, the oxygen concentration during the ultraviolet irradiation for promoting the change of the HTP of the chiral agent is not particularly limited. Accordingly, the ultraviolet irradiation may be performed in an oxygen atmosphere or in a low oxygen atmosphere. Further, it is preferable that the ultraviolet irradiation for promoting the photopolymerization reaction of the liquid crystal compound is performed under heating and/or in a low oxygen atmosphere.

In order to prevent the cholesteric liquid crystal layer from being disordered, it is preferable that the temperature during the ultraviolet irradiation is maintained in a temperature range where the cholesteric liquid crystalline phase is exhibited. Specifically, the temperature during the ultraviolet irradiation is preferably 25° C. to 140° C. and more preferably to 100° C.

In addition, the low oxygen atmosphere during the ultraviolet irradiation may be formed by reducing the oxygen concentration in the atmosphere using a well-known method such as nitrogen substitution. The oxygen concentration is preferably 5000 ppm or lower, more preferably 100 ppm or lower, and still more preferably 50 ppm or lower.

From the viewpoint of stability, the polymerization degree after curing the liquid crystal composition is preferably high, and is preferably 50% or more and more preferably 60% or more. The polymerization degree can be determined by measuring a consumption ratio between polymerizable functional groups using an infrared absorption spectrometry (IR).

[Second Support]

The second support 20 is a member that supports the decorative layer 22.

The second support 20 is not particularly limited, and well-known sheet-shaped materials (film or plate-shaped material) can be used. Specific examples of the second support 20 are the same as the specific examples of the first support 10, and thus the description thereof will not be repeated.

The second support 20 is preferably colorless and transparent. The definition of being colorless and transparent is the same as that of the first support 10, and the description thereof will not be repeated.

The thickness of the second support 20 is not particularly limited and may be appropriately set to a value that can exhibit the effect as the support depending on the material for forming the second support 20.

The thickness of the second support 20 is preferably 20 μm or more and more preferably 40 μm or more.

The upper limit of the thickness of the second support 20 is not particularly limited, and from the viewpoint of preventing the decorative sheet 1 from being unnecessarily thick, is preferably 1000 μm or less, more preferably 800 μm or less, and still more preferably 500 μm or less.

FIG. 1 shows a case where the decorative sheet 1 includes the second support 20. However, the decorative sheet 1 does not need to include the second support 20.

[Decorative Layer]

The decorative layer 22 is a layer itself that can display at least one of a pattern or a color.

In the decorative layer 22, a plurality of opening portions 22a are provided in a thickness direction of the decorative sheet 1.

It is preferable that a pattern in a case where the decorative layer 22 is visually recognized from the front is the same as a pattern where the circularly polarized light reflection layer 14 is visually recognized from the front.

FIG. 5 is a partially enlarged view schematically showing a surface of the decorative layer 22. As shown in FIG. 5, the opening portions 22a are provided on the entire surface of the decorative layer 22.

The distance between the opening portions 22a adjacent to each other in the decorative layer 22 is not particularly limited. Here, the distance between the opening portions 22a adjacent to each other refers to the shortest distance between one opening portion 22a and another opening portions 22a adjacent thereto.

An area ratio of the opening portions 22a in the decorative layer 22 is not particularly limited.

In the present invention, the area ratio of the opening portions refers to a ratio of the total area of the opening portions to the area of the decorative layer obtained assuming that the opening portions are not provided.

In a case where the decorative layer 22 is seen from the front in FIG. 5, the shape of the opening portion 22a is a circular shape, but the present invention is not limited thereto. For example, the shape of the opening portion 22a may be any one of a polygonal shape, an elliptical shape, or an unstructured shape.

A diameter L of the opening portion 22a is preferably 1000 μm or less, more preferably 500 μm or less, still more preferably 300 μm or less, and still more preferably 100 μm or less. In a case where the diameter L of the opening portion 22a is 500 μm or less, the opening portions 22a are inconspicuous in a case where the decorative sheet 1 is visually recognized. Therefore, the designability of the decorative sheet 1 is higher.

The diameter L of the opening portion 22a is preferably 5 μm or more, more preferably 30 μm or more, and still more preferably 60 μm or more. In a case where the diameter L of the opening portion 22a is 30 μm or more, the effects of the present invention are higher.

In the present invention, the diameter of the opening portion corresponds to the equivalent circle diameter. The diameter of the opening portion can be measured using a method described below in Examples.

A method of forming the decorative layer 22 is not particularly limited. For example, the decorative layer 22 can be formed by applying a composition for forming a decorative layer to a surface of the second support 20.

The composition for forming a decorative layer is not particularly limited as long as it can form a layer that can display at least one of a color or a pattern. For example, a coating material, an ink, or the like including well-known materials such as a coloring material (for example, a pigment, or a dye), a resin for fixing the coloring material to the second support 20, and a solvent (for example, water or an organic solvent) can be used.

A method of applying the composition for forming a decorative layer is not particularly limited, and examples thereof include a spray coating method, a squeegee coating method, a flow coating method, a bar coating method, a spin coating method, a dip coating method, a screen printing method, a gravure printing method, an off set printing method, an ink jet printing method, a die coating method, and a curtain coating method.

A method of forming the opening portions 22a is not particularly limited, and examples thereof include a method including: applying the composition for forming a decorative layer to the entire surface of the second support 20 to form a cured layer; and removing a part of the cured layer using laser light or the like. In addition, using a printed pattern where the opening portions 22a are provided in advance, the decorative layer 22 where the opening portions 22a are provided can also be formed.

In addition, for example, using a method of forming the opening portions 22a and overcoating the opening portions 22a with a transparent resin or the like, the opening portions 22a may be filled with the transparent resin.

In the example shown in FIG. 1, a case where the decorative layer 22 has a monolayer structure is shown. The decorative layer 22 has a multi-layer structure.

A visibility-corrected transmittance of the decorative layer 22 in a visible range (hereinafter, also referred to as “visibility-corrected transmittance”) is preferably 80% or less, more preferably 70% or less, still more preferably 60% or less, and still more preferably 50% or less. In a case where the visibility-corrected transmittance is 70% or less, a tint change depending on observation directions is further reduced, and the visibility of the pattern and the color of the decorative layer 22 is improved.

The visibility-corrected transmittance of the decorative layer 22 in a visible range is preferably 20% or more, more preferably 40% or more, and still more preferably 50% or more. In a case where the visibility-corrected transmittance is 40% or more, in an aspect where the decorative sheet 1 is combined with the circularly polarizing plate, the visibility from the circularly polarizing plate side is improved. In an aspect where the decorative sheet 1 is disposed on a display element, the visibility of an image displayed by the display device is improved.

The visibility-corrected transmittance of the decorative layer 22 in a visible range can be adjusted to be in the above-described range, for example, by appropriately adjusting the diameter of the opening portion 22a, the area ratio of the opening portions 22a, the distance between the opening portions 22a adjacent to each other, and the like.

The visibility-corrected transmittance of the decorative layer 22 in a visible range can be measured using a method described below in Examples.

A ratio (the distance between the circularly polarized light reflection layer and the decorative layer/the diameter L of the opening portion 22a) of the distance between the circularly polarized light reflection layer and the decorative layer to the diameter L of the opening portion 22a is preferably 0.1 to 100, more preferably 0.3 to 6, and still more preferably 0.4 to 2. In a case where the ratio is in the above-described range, a tint change from that of the front can be suppressed in a case where the decorative sheet 1 is observed from an oblique direction. In an aspect where the decorative sheet 1 is combined with a circularly polarizing plate, the visibility from the circularly polarizing plate side is improved. In an aspect where the decorative sheet 1 is disposed on a display element, the visibility of an image displayed by the display device is improved.

Here, the distance between the circularly polarized light reflection layer and the decorative layer refers to the straight-line distance from the surface of the circularly polarized light reflection layer close to the decorative layer to the decorative layer close to the circularly polarized light reflection layer. For example, the distance between the circularly polarized light reflection layer 14 and the decorative layer 22 in FIG. 1 is the same as the thickness of the second support 20.

The distance between the circularly polarized light reflection layer and the decorative layer can be obtained by calculating an arithmetic mean value of distances at any 10 points based on a cross-sectional cell image of the decorative sheet.

[Other Layers]

The decorative sheet 1 may further include other layers (other members) including the above-described layers. Examples of the other layers (the other members) include a pressure sensitive adhesive layer, a λ/4 retardation plate, and a circularly polarizing plate.

<Pressure Sensitive Adhesive Layer>

The pressure sensitive adhesive layer can be used for improving adhesiveness of the layers. For example, FIG. 1 shows a case where the second support 20 is directly formed on the surface of the circularly polarized light reflection layer 14. In order to improve the adhesiveness between the second support 20 and the circularly polarized light reflection layer 14, the pressure sensitive adhesive layer may be disposed between the second support 20 and the circularly polarized light reflection layer 14.

As a pressure sensitive adhesive or an adhesive used in the pressure sensitive adhesive layer, for example, a pressure sensitive adhesive (for example, an acrylic pressure sensitive adhesive) or an adhesive (for example, an ultraviolet curable adhesive or a polyvinyl alcohol adhesive) that is typically used can be used. Specific examples of the pressure sensitive adhesive and the adhesive include pressure sensitive adhesives described in paragraphs “0100” to “0115” of JP2011-037140A and paragraphs “0155” to “0171” of JP2009-292870A.

The thickness of the pressure sensitive adhesive layer is not particularly limited and is preferably 1 to 30 μm, more preferably 2 to 20 μm, and still more preferably 4 to 15 μm.

<λ/4 Retardation Plate>

It is preferable that the λ/4 retardation plate is disposed on a surface side of the circularly polarized light reflection layer 14 opposite to the decorative layer 22.

The decorative sheet 1 includes the λ/4 retardation plate such that the decorative sheet 1 can be used as a decorating member having high applicability.

The “λ/4 retardation plate” is a plate having a λ/4 function, and is specifically, a plate having a function of converting linearly polarized light with a specific wavelength into circularly polarized light (or converting circularly polarized light into linearly polarized light).

For example, in a case where a surface of a liquid crystal display element (display) is decorated with the decorative sheet 1 including the λ/4 retardation plate, decoration having unique designability can be realized where the color of the decorative sheet is seen only during turn-off of the display or black display and the decorative sheet is transparent and has no presence during white display. That is, with the liquid crystal display device where a composite film including the decorative sheet 1 and the λ/4 retardation plate is provided on a surface (image display surface), the liquid crystal display device having unique designability can be realized where the color of the decorative sheet 1 is seen only during turn-off of the display or black display and the decorative sheet is transparent and has no presence during white display.

In addition, the decorative sheet 1 including the λ/4 retardation plate can also be utilized as a reflection plate such as a reflective liquid crystal display element or a semi-transmissive liquid crystal liquid crystal display element.

The decorative sheet 1 can be used as an automobile interior material using the above-described unique designability. In addition, in an aspect where the λ/4 retardation plate is further provided on the visible side of the decorative sheet 1, by using the decorative layer 22 side of the decorative sheet 1 for decorating a dashboard in front of the windshield of a vehicle, the reflected glare of the dashboard on the windshield can be resolved. That is, in a case where the decorative sheet 1 further including the λ/4 retardation plate is applied to an automobile interior material, the reflected glare of the dashboard on the windshield can be resolved.

In addition, the decorative sheet 1 including the λ/4 retardation plate is not limited to this use and can be used in various uses to prevent an article applied to decoration from being reflected on a reflector.

Specific examples of the λ/4 retardation plate include US2015/0277006A.

For example, specific examples of an aspect in which the λ/4 retardation plate has a monolayer structure include a stretched polymer film and a retardation film in which an optically-anisotropic layer having a λ/4 function is provided on a support. Further, specific examples of an aspect in which the λ/4 retardation plate has a multilayer structure include a broadband λ/4 retardation plate where a λ/4 retardation plate and a λ/2 retardation plate are laminated.

The λ/4 retardation plate can be formed, for example, by applying a liquid crystal composition including a liquid crystal compound.

It is more preferable that the λ/4 retardation plate is a retardation film including one or more layers including at least one liquid crystal compound (such as a disk-like liquid crystal compound or a rod-like liquid crystal compound) formed by polymerizing a liquid crystal monomer exhibiting a nematic liquid crystal layer or a smectic liquid crystal layer.

Further, it is still more preferable to use a liquid crystal compound having reverse wavelength dispersibility as the λ/4 retardation plate having excellent optical performance. Specifically, a liquid crystal compound represented by Formula (II) described in WO2017/043438A is preferably used. The details of a method of preparing the λ/4 retardation plate formed of a liquid crystal compound having reverse wavelength dispersibility can be found in Examples 1 to 10 of WO2017/043438A and Example 1 of JP2016-91022A.

The thickness of the λ/4 retardation plate is not particularly limited and is preferably 0.1 to 100 μm and more preferably 0.5 to 5 μm.

<Circularly Polarizing Plate>

It is preferable that the circularly polarizing plate is disposed on a surface side of the circularly polarized light reflection layer 14 opposite to the decorative layer 22.

The decorative sheet 1 including the circularly polarizing plate can be made to have unique designability where, in a case where the visible side is bright through a film such as a half mirror, the decorative sheet 1 is visually recognized as a decorative material without the back side seeing therethrough and in a case where the back side is bright, the decorative sheet 1 is visually recognized as a transparent film.

Examples of the circularly polarizing plate include a plate where a linearly polarizing plate and a λ/4 retardation plate are laminated. In a configuration of the circularly polarizing plate, the λ/4 retardation plate and the linearly polarizing plate are disposed in this order from the circularly polarized light reflection layer 14 side. The linearly polarizing plate and the λ/4 retardation plate are disposed to make a slow axis of the λ/4 retardation plate and a transmission axis of the linearly polarizing plate match with each other such that, for example, light incident from the linearly polarizing plate side is converted into left circularly polarized light or right circularly polarized light by the λ/4 retardation plate. More specifically, it is preferable that the linearly polarizing plate and the λ/4 retardation plate are disposed such that an angle between the slow axis of the λ/4 retardation plate and the transmission axis of the linearly polarizing plate is typically 45°.

In a case where the decorative sheet 1 includes the circularly polarizing plate, the above-described pressure sensitive adhesive layer may be disposed between the circularly polarizing plate and the circularly polarized light reflection layer 14.

The thickness of the circularly polarizing plate is not particularly limited and is preferably 1 to 150 μm, more preferably 2 to 100 μm, and still more preferably 5 to 60 μm.

[Physical Properties And The Like of Decorative Sheet]

A visibility-corrected transmittance of circularly polarized light of the decorative sheet 1 in a visible range (hereinafter, also referred to as “visibility-corrected circularly polarized light transmittance”) is preferably 20% or more, more preferably 30% or more, still more preferably 40% or more, and still more preferably 50% or more. In a case where the visibility-corrected circularly polarized light transmittance is 30% or more, in a case where the decorative sheet 1 is applied to a display device, the transmittance during the display ON (turn-on) of the display device is excellent, and the visibility of an image displayed by the display device is improved.

The visibility-corrected circularly polarized light transmittance of the decorative sheet 1 in a visible range is preferably 95% or less, more preferably 75% or less, and still more preferably 65% or less. In a case where the visibility-corrected circularly polarized light transmittance is 75% or less, a tint change from that of the front can be suppressed in a case where the decorative sheet 1 is observed from an oblique direction, and the visibility of an image can be improved in a case where the decorative sheet 1 is applied to a display device.

The visibility-corrected circularly polarized light transmittance of the decorative sheet 1 in a visible range can be adjusted to be in the above-described range, for example, by appropriately adjusting the diameter of the opening portion 22a of the decorative layer 22, the area ratio of the opening portions 22a of the decorative layer 22, the film thickness during the formation of the circularly polarized light reflection layer 14, the bandwidth in the reflection spectrum, and the like.

The visibility-corrected circularly polarized light transmittance of the decorative sheet 1 in a visible range can be measured using a method described below in Examples.

The thickness of the decorative sheet 1 is not particularly limited and is preferably 50 to 1500 μm, more preferably 100 to 1000 μm, and still more preferably 150 to 500 μm.

[Display Device]

A display device (image display apparatus) according to an embodiment of the present invention includes: a display element; and the above-described decorative sheet that is disposed on the above-described display element. In the display device according to the embodiment of the present invention, it is preferable that the decorative layer, the circularly polarized light reflection layer, and the display element are disposed in this order from the visible side.

The display element used in the display device according to the embodiment of the present invention is not particularly limited, and examples thereof include a liquid crystal cell, an organic electroluminescence (organic EL) display panel, and a plasma display panel.

Among these, a liquid crystal cell or an organic EL display panel is preferable, and an organic EL display panel is more preferable. That is, in the display device according to the embodiment of the present invention, a liquid crystal display device including a liquid crystal cell as a display element or an organic EL display device including an organic EL display panel as a display element is preferable.

Emitted light of the display element is preferably linearly polarized light.

In a case where the display device includes the decorative sheet and an image is not displayed by the display element, the pattern of the decorative sheet itself is visually recognized. Here, the display device according to the embodiment of the present invention includes the above-described decorative sheet. Therefore, in a case where an image is not displayed by the display element, the pattern of the decorative sheet can be visually recognized favorably from any direction, and a tint change depending on directions is also small.

Examples of a preferable aspect of the display device according to the embodiment of the present invention include an automobile interior material.

[Liquid Crystal Display Device]

Preferable examples of the liquid crystal display device that is an example of the display device according to the embodiment of the present invention include an aspect where the decorative layer including the above-described decorative sheet, the circularly polarized light reflection layer including the above-described decorative sheet, and a liquid crystal cell are disposed in this order from the visible side.

The liquid crystal cell used in the liquid crystal display device is preferably in a vertical alignment (VA) mode, an optically compensated bend (OCB) mode, an in-plane-switching (IPS) mode, or a twisted nematic (TN) mode, but the liquid crystal cell is not limited thereto.

In the liquid crystal cell in the TN mode, during non-voltage application, rod-like liquid crystal molecules (rod-like liquid crystal compound) are substantially horizontally aligned and further twisted and aligned at 60° to 120°. The TN-mode liquid crystal cell is most often used in a color TFT liquid crystal display device and is described in numerous documents.

In the liquid crystal cell in the VA mode, during non-voltage application, rod-like liquid crystal molecules are substantially vertically aligned. Examples of the liquid crystal cell in the VA mode includes (1) a liquid crystal cell in the VA mode in a narrow sense where rod-like liquid crystal molecules are substantially vertically aligned during non-voltage application and are substantially horizontally aligned during voltage application (described in JP1990-176625A (JP-H2-176625A)), (2) a liquid crystal cell (in a multi-domain vertical alignment (MVA) mode) where multiple domains are provided in the VA mode (described in SID97, Digest of tech. Papers (proceedings), 28 (1997) 845) to expand the viewing angle, (3) a liquid crystal cell in an axially symmetric aligned microcell (n-ASM) mode in which rod-like liquid crystal molecules are substantially vertically aligned during non-voltage application and are twisted and aligned in multi-domains during voltage application (described in proceedings of Japanese Liquid Crystal Conference, pp. 58 to 59 (1998)), and (4) a liquid crystal cell in a SURVIVAL mode (presented at liquid crystal cell (LCD) International 98). Further, the liquid crystal cell in the VA mode may be any of a patterned vertical alignment (PVA) type, a photo-alignment (optical alignment) type, or a polymer-sustained alignment (PSA) type. The details of these modes are described in JP2006-215326A and JP2008-538819A.

In the liquid crystal cell in the IPS mode, rod-like liquid crystal molecules are aligned substantially parallel to the substrate, and an electric field parallel to a substrate surface is applied such that the liquid crystal cells respond to the electric field in a planar manner. In the IPS mode, the liquid crystal cell is in black display during non-electric field application, and absorption axes of a pair of upper and lower polarizing plates are orthogonal to each other. A method of reducing leakage light during black display in an oblique direction and improving the viewing angle using an optical compensation sheet is disclosed in JP1998-54982A (JP-H10-54982A), JP1999-202323A (JP-H11-202323A), JP1997-292522A (JP-H9-292522A), JP1999-133408A (JP-H11-133408A), JP1999-305217A (JP-H11-305217A), and JP1998-307291A (JP-H10-307291A).

[Organic EL Display Device]

Preferable examples of the organic EL display device that is an example of the display device according to the embodiment of the present invention include an aspect where the decorative layer including the above-described decorative sheet, the circularly polarized light reflection layer including the above-described decorative sheet, and an organic EL display panel are disposed in this order from the visible side.

Further, the organic EL display panel is a display panel formed of an organic EL element where an organic light emitting layer (organic electroluminescence layer) is sandwiched between electrodes (between a cathode and an anode). The configuration of the organic EL display panel is not particularly limited, and a well-known configuration is adopted.

### EXAMPLES

Hereinafter, the present invention will be described in more detail based on the following examples. Materials, used amounts, ratios, treatment details, treatment procedures, and the like shown in the following examples can be appropriately changed within a range not departing from the scope of the present invention. Accordingly, the scope of the present invention is not limited to the following examples.

<Formation of Circularly Polarized Light Reflection Layer 1>

As a support, a polyethylene terephthalate (PET) film (COSMOSHINE A4100, manufactured by Toyobo Co., Ltd.) having a thickness of 100 μm was prepared. This PET film includes an easy adhesion layer on one surface. A coating liquid 1 for forming an underlayer having the following composition was applied to a surface of the PET film where the easy adhesion layer was not provided using a #16 wire bar coater. Next, the coating film was dried at 80° C. for 120 seconds to prepare a PET film with an underlayer 1.

[Coating Liquid 1 for Forming Underlayer]

| | | |
|---|---|---|
| The following modified polyvinyl | 10 | parts by mass |
| alcohol | | |
| Water | 370 | parts by mass |
| Methanol | 120 | parts by mass |
| Glutaraldehyde (crosslinking agent) | 0.5 | parts by mass |

Modified Polyvinyl Alcohol

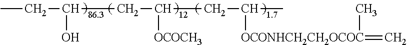

A composition shown below was stirred and dissolved in a container held at 25° C. to prepare a coating liquid 1 for forming a circularly polarized light reflection layer.

(Coating Liquid 1 for Forming Circularly Polarized Light Reflection Layer)

| | | |
|---|---|---|
| Methyl ethyl ketone | 143.0 | parts by mass |
| Mixture LC1 of the following rod-like liquid crystal compounds | 100.0 | parts by mass |
| IRGACURE 127 (manufactured by Ciba-Geigy) | 0.5 | parts by mass |
| Chiral agent A having the following structure | 2.0 | parts by mass |
| Chiral agent B having the following structure | 1.0 | parts by mass |
| Surfactant F1 having the following structure | 0.1 | parts by mass |

Mixture LC1 of Rod-Like Liquid Crystal Compounds 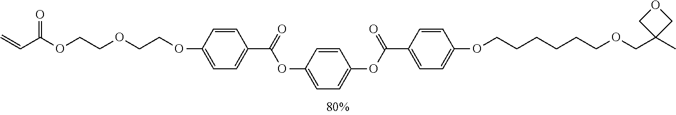 [SMILES: C=CC(=O)OCCOCCOc1ccc(C(=O)Oc2ccc(OC(=O)c3ccc(OCCCCCCOCC4(C)COC4)cc3)cc2)cc1] 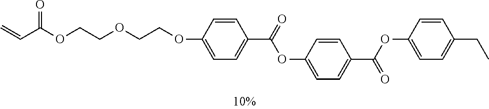 [SMILES: C=CC(=O)OCCOCCOc1ccc(C(=O)Oc2ccc(C(=O)Oc3ccc(CC)cc3)cc2)cc1] 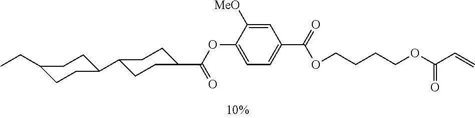 [SMILES: C=CC(=O)OCCCCOC(=O)c1ccc(OC(=O)C2CCC(C3CCC(CC)CC3)CC2)c(OC)c1]
Numerical values in the formulae are represented by mass %. Me represents a methyl group. 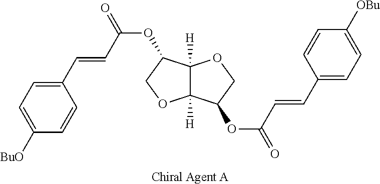
In the formula, Bu represents a butyl group.

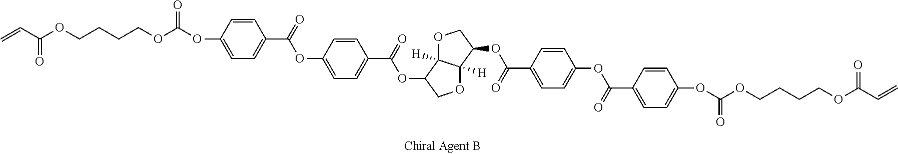 [SMILES: C=CC(=O)OCCCCOC(=O)Oc1ccc(C(=O)Oc2ccc(C(=O)OC3CO[C@H]4[C@@H]3OC[C@H]4OC(=O)c3ccc(OC(=O)c4ccc(OC(=O)OCCCCOC(=O)C=C)cc4)cc3)cc2)cc1]

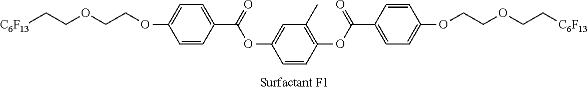

The prepared coating liquid 1 for forming a circularly polarized light reflection layer was applied using a #8 wire bar coater to the surface of the prepared underlayer 1, and was dried at 100° C. for 60 seconds.

Next, the coating film was irradiated with light from a metal halide lamp at 25° C. and an irradiation dose of 72 mJ through an optical filter SH0350 (manufactured by Asahi Spectra Co., Ltd.) and an exposure mask having a grain pattern, and was further irradiated with light from a metal halide lamp in a low oxygen atmosphere (100 ppm or less) at 120° C. and an irradiation dose of 300 mJ. As a result, the PET film 1 including the circularly polarized light reflection layer 1 having a grain pattern was prepared.

In a case where a cross-sectional SEM (scanning electron microscope) image of the circularly polarized light reflection layer 1 was checked, the liquid crystal layer had a pitch gradient structure in which an interval having a stripe pattern derived from a helical pitch changed in a film thickness direction.

<Formation of Circularly Polarized Light Reflection Layer 2>

A composition shown below was stirred and dissolved in a container held at 25° C. to prepare a coating liquid 2-1 for forming a circularly polarized light reflection layer.

(Coating Liquid 2-1 for Forming Circularly
Polarized Light Reflection Layer)

| | |
|---|---|
| Methyl ethyl ketone | 241.7 parts by mass |
| Mixture LC1 of the above-described | 100.0 parts by mass |
| rod-like liquid crystal compounds | |
| IRGACURE 127 (manufactured by Ciba-Geigy) | 0.5 parts by mass |
| Chiral agent A having the above-described structure | 1.3 parts by mass |
| Chiral agent B having the following structure | 1.0 parts by mass |
| Surfactant F1 having the above-described structure | 0.1 parts by mass |

Using the same method as that of the circularly polarized light reflection layer 1, the PET film with the underlayer 1 was prepared. The prepared coating liquid 2-1 for forming a circularly polarized light reflection layer was applied using a #3 wire bar coater to the surface of the prepared underlayer 1, and was dried at 100° C. for 60 seconds.

Next, the coating film was irradiated with light from a metal halide lamp in a low oxygen atmosphere (100 ppm or less) at 25° C. and an irradiation dose of 60 mJ through an exposure mask for forming a grain pattern. Next, the coating film was irradiated with light from a metal halide lamp at 120° C. and an irradiation dose of 100 mJ through an optical filter SH0350 (manufactured by Asahi Spectra Co., Ltd.) and was held at 120° C. for 2 minutes. Next, the coating film was further irradiated with light from a metal halide lamp in a low oxygen atmosphere (100 ppm or less) at 120° C. and an irradiation dose of 300 mJ. As a result, a circularly polarized light reflection layer 2-1 was formed.

Coating liquids 2-2 to 2-6 for forming a circularly polarized light reflection layer were prepared using the same method as that of the coating liquid 2-1 for forming a circularly polarized light reflection layer, except that the addition amount of the chiral agent B gradually increased.

Next, the prepared coating liquid 2-2 for forming a circularly polarized light reflection layer was applied using a #3 wire bar coater to the surface of the prepared circularly polarized light reflection layer 2-1, and was dried at 100° C. for 60 seconds. Further, a circularly polarized light reflection layer 2-2 was laminated using the same method as the procedure of preparing the circularly polarized light reflection layer 2-1. By laminating the circularly polarized light reflection layers 2-3 to 2-6 through the same procedure, a circularly polarized light reflection layer 2 was prepared.

The circularly polarized light reflection layer 2 had a configuration in which the six circularly polarized light reflection layers 2-1 to 2-6 in total were laminated on the underlayer 1, and the decoration pattern was substantially not similar to that of the circularly polarized light reflection layer 1.

In a case where a cross-sectional SEM image of the circularly polarized light reflection layer 2 was checked, in the liquid crystal layer, intervals of helical pitches of the respective layers were uniform in the film thickness direction, but helical pitches of the layers were different. The liquid crystal layer did not have the pitch gradient structure.

<Formation of Circularly Polarized Light Reflection Layer 3>

Coating liquids 3-1 to 3-6 for forming a circularly polarized light reflection layer were prepared using the same method as that of the coating liquid 2-1 for forming a circularly polarized light reflection layer, except that the addition amounts of the chiral agent A and the chiral agent B were adjusted.

Using the same method as that of the circularly polarized light reflection layer 1, the PET film with the underlayer 1 was prepared, and the underlayer 1 was rubbed. By laminating the circularly polarized light reflection layers 3-1 to 3-6 on the rubbed surface of the underlayer through the same procedure as that of the circularly polarized light reflection layer 2, a circularly polarized light reflection layer 3 was prepared. The circularly polarized light reflection layer 3 had a configuration in which the six circularly polarized light reflection layers 3-1 to 3-6 in total were laminated on the rubbed underlayer, and the decoration pattern was substantially not similar to that of the circularly polarized light reflection layer 1 in a view right above the top.

In a case where a cross-sectional SEM image of the circularly polarized light reflection layer 3 was checked, in the liquid crystal layer, intervals of helical pitches of the respective layers were uniform in the film thickness direction, but helical pitches of the layers were different. The liquid crystal layer did not have the pitch gradient structure.

<Formation of Circularly Polarized Light Reflection Layer 4>

Using the same method as that of the circularly polarized light reflection layer 1, the PET film with the underlayer 1 was prepared, and the underlayer 1 was slightly rubbed. A circularly polarized light reflection layer 4 was prepared using the same method as that of preparing the circularly polarized light reflection layer 1, except that the rubbed underlayer 1 was used as the underlayer. The decoration pattern of the circularly polarized light reflection layer 4 was substantially not similar to that of the circularly polarized light reflection layer 1.

In a case where a cross-sectional SEM image of the circularly polarized light reflection layer 4 was checked, the liquid crystal layer had a pitch gradient structure in which an interval having a stripe pattern derived from a helical pitch changed in a film thickness direction.

<Formation of Circularly Polarized Light Reflection Layer 5>

A circularly polarized light reflection layer 5 was prepared using the same method as that of the circularly polarized light reflection layer 4, except that rubbing conditions of the underlayer were adjusted, the bar number during the formation of the circularly polarized light reflection layer and the UV irradiation dose during the use of the optical filter SH0350 were adjusted, and the pattern of the exposure mask was changed from the grain pattern to a marble pattern.

In a case where a cross-sectional SEM image of the circularly polarized light reflection layer 5 was checked, the liquid crystal layer had a pitch gradient structure in which an interval having a stripe pattern derived from a helical pitch changed in a film thickness direction.

<Formation of Circularly Polarized Light Reflection Layer 6>

A circularly polarized light reflection layer 6 was prepared using the same method as that of the circularly polarized light reflection layer 1, except that the coating liquid 1 for forming an underlayer was changed to a coating liquid 6 for forming an underlayer and a #3.6 wire bar was used for applying the underlayer.

In a case where a cross-sectional SEM image of the circularly polarized light reflection layer 6 was checked, the liquid crystal layer had a pitch gradient structure in which an interval having a stripe pattern derived from a helical pitch changed in a film thickness direction.

[Coating Liquid 6 for Forming Underlayer]

| | | |
|---|---|---|
| KAYARAD PET30 | 25 | parts by mass |
| (manufactured by Nippon Kayaku Co., Ltd.) | | |
| DCP | 75 | parts by mass |
| (manufactured by Shin-Nakamura | | |
| Chemical Co., Ltd.) | | |
| IRGACURE 907 | 3.0 | parts by mass |
| (manufactured by Ciba-Geigy) | | |
| KAYACURE DETX | 1.0 | part by mass |
| (manufactured by Nippon Kayaku Co., Ltd.) | | |
| The following surfactant F2 | 0.01 | parts by mass |
| Methyl isobutyl ketone | 243 | parts by mass |

Surfactant F2

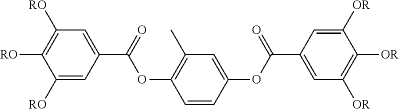

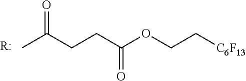

<Formation of Decorative Layer 1 where Opening Portions Were Provided>

A PMMA film having a thickness of 125 μm was prepared, and was printed through opening portions using a digital offset printing machine. As a result, a decorative layer 1 having a grain pattern where the opening portions were provided was prepared.

<Formation of Decorative Layers 2 to 5 and 7 where Opening Portions Were Provided>

Decorative layers 2 to 5 and 7 where the opening portions were provided were prepared using the same method as that of the decorative layer 1 where the opening portions were provided, except that the printed pattern was adjusted.

<Formation of Decorative Layer 6 where Opening Portions Were Provided>

A decorative layer 6 where the opening portions were provided was prepared using the same method as that of the decorative layer 1 where the opening portions were provided, except that a polymethyl methacrylate (PMMA) film having a thickness of 75 μm was used and the printed pattern was adjusted.

### Preparation of Decorative Sheets According to Examples 1 to 8

Regarding each of the decorative layers where the opening portions were provided that were prepared using the combinations shown in Table 1, the prepared circularly polarized light reflection layer was bonded using a pressure sensitive adhesive (SK2057, manufactured by Soken Chemical & Engineering Co., Ltd.) to a surface of the PMMA film where the decorative layer was not formed. The amount of the pressure sensitive adhesive attached was adjusted such that the thickness of a layer (pressure sensitive adhesive layer) formed of the pressure sensitive adhesive was 25 μm.

Further, by peeling off the PET film, decorative sheets according to Examples 1 to 8 were prepared.

### Preparation of Decorative Sheet According to Example 9

Regarding the decorative layer 6 where the opening portions were provided that were prepared using the combinations shown in Table 1, the prepared circularly polarized light reflection layer 1 was bonded using a pressure sensitive adhesive (Opteria D692, manufactured by Lintec Corporation) to a surface of the PMMA film where the decorative layer was not formed. The amount of the pressure sensitive adhesive attached was adjusted such that the thickness of a layer (pressure sensitive adhesive layer) formed of the pressure sensitive adhesive was 15 μm.

Further, by peeling off the PET film, a decorative sheet according to Example 9 was prepared.

### Preparation of Decorative Sheets According to Examples 10 to 12

Regarding each of the decorative layers where the opening portions were provided that were prepared using the combinations shown in Table 1, the prepared circularly polarized light reflection layer was bonded using a pressure sensitive adhesive (SK2057, manufactured by Soken Chemical & Engineering Co., Ltd.) to a surface of the PMMA film where the decorative layer was not formed. Next, the PET film was peeled off. The amount of the pressure sensitive adhesive attached was adjusted such that the thickness of a layer (pressure sensitive adhesive layer) formed of the pressure sensitive adhesive was 25 μm.

A circularly polarizing plate 1 was separately prepared using the same method as that of a circularly polarizing plate 21 described in JP6276393B, and the optically-anisotropic layer of the circularly polarizing plate 1 and the circularly polarized light reflection layer of the decorative sheet were bonded to each other using a pressure sensitive adhesive (SK2057, manufactured by Soken Chemical & Engineering Co., Ltd.). As a result, decorative sheets according to Examples 10 to 12 were prepared. The amount of the pressure sensitive adhesive attached was adjusted such that the thickness of a layer (pressure sensitive adhesive layer) formed of the pressure sensitive adhesive was 25 μm.

Here, the angle between the optically-anisotropic layer of the circularly polarizing plate 1 and the absorption axis of the polarizer was any one of 45° clockwise or 45° counterclockwise, the circularly polarizing plate 1 was disposed on the circularly polarized light reflection layer side of the decorative sheet, and an axis relationship between the optically-anisotropic layer of the circularly polarizing plate 1 and the absorption axis of the polarizer was set such that a scenery on the depth side of the decorative sheet was able to be seen from the circularly polarizing plate.

### Preparation of Decorative Sheet According to Comparative Example 1

The prepared decorative layer 7 where the opening portions were provided was used as a decorative sheet according to Comparative Example 1.

### Preparation of Decorative Sheet According to Comparative Example 2

The prepared circularly polarized light reflection layer 1 was used as a decorative sheet according to Comparative Example 2.

<Evaluation of Decorative Sheet Alone>

The prepared reflective sheet was evaluated as follows.

(Diameter of Opening Portion)

The opening portion of the decorative layer where the opening portions were provided was observed with an optical microscope to calculate the diameter of the opening portion. The same measurement was performed at 10 points in a plane and the arithmetic mean value thereof was set as the diameter of the opening portions.

(Visibility-Corrected Transmittance)

Using a spectrophotometer (UV-3150, manufactured by Shimadzu Corporation), a transmission spectrum of the decorative layer where the opening portions were provided was measured in a wavelength range of 380 to 780 nm, and the visibility was corrected using a 2 degree field of view (C light source) according to JIS Z8701 to calculate a visibility-corrected transmittance. The baseline was corrected using the PMMA film used for preparing the decorative layer where the opening portions were provided.

(Average Value of Peak-To-Peak Distances of Waving Structure)

In the cross-sectional SEM image of the formed cholesteric liquid crystal layer, the measurement was performed using the above-described method of measuring the average value peak-to-peak distances of the waving structure.

(Measurement of Integral Reflectivity Excluding Specular Reflection Component in Visible Range)

Using a device in which a large integrating sphere device (ILV-471, manufactured by JASCO Corporation) was attached to a spectrophotometer (V-550, manufactured by JASCO Corporation) such that light was incident from the circularly polarized light reflection layer side, an integral reflection spectrum of the circularly polarized light reflection layer excluding a specular reflection component was measured using optical trap in a state where specularly reflected light was not included. In the obtained integral reflection spectrum, a maximum reflectivity at a wavelength of 380 to 780 nm was measured.

(Evaluation of Visibility-Corrected Circularly Polarized Light Transmittance)

A circularly polarizing plate 2 was separately prepared using the same method as that of a circularly polarizing plate 27 described in JP6276393B. Here, the angle between the optically-anisotropic layer of the circularly polarizing plate 2 and the absorption axis of the polarizer was 45°, the circularly polarizing plate 2 was disposed on the circularly polarized light reflection layer side of the decorative sheet, and an axis relationship between the optically-anisotropic layer of the circularly polarizing plate 2 and the absorption axis of the polarizer was set such that a scenery on the depth side of the decorative sheet was able to be seen from the circularly polarizing plate.

The prepared circularly polarizing plate 2 was disposed in a spectrophotometer (UV-3150, manufactured by Shimadzu Corporation), circularly polarized light was used as incidence light to measure a transmission spectrum of the circularly polarized light of the decorative sheet in a wavelength range of 380 to 780 nm, and the visibility was corrected using a 2 degree field of view (C light source) according to JIS Z8701 to calculate a visibility-corrected circularly polarized light transmittance. The baseline was corrected using the PMMA film used for preparing the decorative sheet instead of the decorative sheet.

In addition, in Examples 10 to 12 as the aspect where the decorative sheet includes the circularly polarizing plate, the spectrum of the decorative sheet was measured in a state where the circularly polarizing plate 2 provided in the spectrophotometer was removed for only the sample measurement.

(Evaluation of Visibility)

The decorative sheet was disposed on black paper, and in a case where the decorative sheet was seen from the front and from a 45 degree oblique direction, the visibility of the decorative pattern was evaluated based on the following standards.
A: the decorative pattern can be clearly visually recognized.
B: the decorative pattern can be visually recognized.
C: the visibility of the decorative pattern is poor (unclear), which is not allowable.

(Evaluation of Tint Change)

The decorative sheet was disposed on black paper and was observed from a 15 degree oblique direction and from a 45 degree oblique direction. A tint change from the front was checked by visual inspection and was evaluated based on the following standards.
A: a tint difference of the decorative pattern between the front and the 15 degree oblique direction or the 45 degree oblique direction does not attract attention at all.
B: a tint difference of the decorative pattern between the front and the 15 degree oblique direction or the 45 degree oblique direction is slightly visually recognized.
C: a tint difference of the decorative pattern between the front and the 15 degree oblique direction or the 45 degree oblique direction is visually recognized but is allowable.
D: a tint difference of the decorative pattern between the front and the 15 degree oblique direction or the 45 degree oblique direction is clearly visually recognized which is not allowable).

TABLE 1

| | | | | | | | | | | | | | | | Comparative | Comparative |
|---|---|---|---|---|---|---|---|---|---|---|---|---|---|---|---|---|
| | | | Example | Example | Example | Example | Example | Example | Example | Example | Example | Example | Example | Example | Example | Example |
| | | | 1 | 2 | 3 | 4 | 5 | 6 | 7 | 8 | 9 | 10 | 11 | 12 | 1 | 2 |
| Decorative | Kind of decorative | | 1 | 1 | 1 | 1 | 2 | 3 | 4 | 5 | 6 | 1 | 1 | 4 | 7 | — |
| layer | layer where | | | | | | | | | | | | | | | |
| where | opening portions | | | | | | | | | | | | | | | |
| opening | are provided | | | | | | | | | | | | | | | |
| portions | Decorative pattern | | Grain | Grain | Grain | Grain | Marble | Grain | Grain | Grain | Grain | Grain | Grain | Grain | Grain | — |
| are provided | Diameter | | 40 | 40 | 40 | 40 | 40 | 300 | 10 | 500 | 300 | 40 | 40 | 10 | 25 | — |
| | of opening | | | | | | | | | | | | | | | |
| | portion [μm] | | | | | | | | | | | | | | | |
| | (Distance between | | 3.8 | 3.8 | 3.8 | 3.8 | 3.8 | 0.5 | 15.0 | 0.30 | 0.30 | 3.8 | 3.8 | 15.0 | — | — |
| | ch liquid crystal | | | | | | | | | | | | | | | |
| | layer and decorative | | | | | | | | | | | | | | | |
| | layer)/(Diameter | | | | | | | | | | | | | | | |
| | of opening portion) | | | | | | | | | | | | | | | |
| | Visibility-corrected | | 45 | 45 | 45 | 45 | 33 | 70 | 45 | 75 | 70 | 45 | 45 | 45 | 65 | |
| | transmittance [%] | | | | | | | | | | | | | | | |
| Circularly | Kind of | | 1 | 2 | 3 | 4 | 5 | 1 | 6 | 1 | 1 | 1 | 3 | 6 | — | 1 |
| polarized | circularly | | | | | | | | | | | | | | | |
| light | polarized light | | | | | | | | | | | | | | | |
| reflection | reflection layer | | | | | | | | | | | | | | | |
| layer (ch | Decorative pattern | | Grain | Grain | Grain | Grain | Marble | Grain | Grain | Grain | Grain | Grain | Grain | Grain | — | Grain |
| liquid crystal | Average | | 7 | 7 | ∞ | 54 | 1.0 | 7 | 12 | 7 | 7 | 7 | ∞ | 12 | — | 7 |
| layer) | value of | | | | (Specular | | | | | | | | (Specular | | | |
| | peak-to-peak | | | | reflection) | | | | | | | | reflection) | | | |
| | distances | | | | | | | | | | | | | | | |
| | of waving | | | | | | | | | | | | | | | |
| | structure [μm] | | | | | | | | | | | | | | | |
| | Maximum value | | 31 | 31 | 0 | 31 | 8 | 31 | 41 | 31 | 31 | 31 | 0 | 41 | — | 31 |
| | reflectivity | | | | | | | | | | | | | | | |
| | excluding | | | | | | | | | | | | | | | |
| | specular | | | | | | | | | | | | | | | |
| | of integral | | | | | | | | | | | | | | | |
| | reflection | | | | | | | | | | | | | | | |
| | component in | | | | | | | | | | | | | | | |
| | visible range [%] | | | | | | | | | | | | | | | |
| | Change of | | Present | None | None | Present | Present | Present | Present | Present | Present | Present | None | Present | — | Present |
| | helical pitch in | | | | | | | | | | | | | | | |
| | film thickness | | | | | | | | | | | | | | | |
| | direction | | | | | | | | | | | | | | | |
| λ/4 retardation plate | | | — | — | — | — | — | — | — | — | — | Present | Present | Present | — | — |
| Polarizing plate | | | — | — | — | — | — | — | — | — | — | Present | Present | Present | — | — |
| Visibility-corrected circularly | | | 36% | 36% | 36% | 32% | 27% | 66% | 25% | 72% | 66% | 36% | 36% | 25% | 41% | — |
| polarized light transmittance | | | | | | | | | | | | | | | | |
| Evaluation of | Visibility | Front | A | A | A | A | A | A | A | A | A | A | A | A | C | A |
| decorative | | 45 degree | A | A | B | B | A | A | A | A | A | A | B | A | C | A |
| sheet alone | | oblique | | | | | | | | | | | | | | |
| | | direction | | | | | | | | | | | | | | |
| | Tint | 15 degree | A | A | C | B | A | A | A | A | A | A | C | A | — | B |
| | change | oblique | | | | | | | | | | | | | | |
| | | direction | | | | | | | | | | | | | | |
| | | 45 degree | A | A | C | B | A | B | A | C | C | A | C | A | — | D |
| | | oblique | | | | | | | | | | | | | | |
| | | direction | | | | | | | | | | | | | | |

As shown in Table 1, it was clarified that, in a case where the decorative sheet according to the embodiment of the present invention is used, a tint change depending on observation directions is small, and the visibility of a pattern in any observation direction is excellent (Examples).

It was clarified from a comparison between Examples 1 and 4, a comparison between Examples 2 and 3, and a comparison between Examples 10 and 11 that, in a case where an average value of peak-to-peak distances of the waving structure is in a range of 0.5 to 50 μm, a tint change depending on observation directions is further reduced, and the visibility of a pattern in any observation direction is further improved (Examples 1, 2, and 10).

It was clarified from a comparison between Examples 2 and 3 and a comparison between Examples 10 and 11 that, in a case where a maximum value of an integral reflectivity of the circularly polarized light reflection layer excluding a specular reflection component in a wavelength range of 380 to 780 nm is 7% or more, a tint change depending on observation directions is further reduced, and the visibility of a pattern in any observation direction is further improved (Examples 2 and 10).

It was clarified from a comparison between Examples 1, 6, and 8 that, in a case where the visibility-corrected transmittance of the decorative layer in a visible range is 70% or less, a tint change depending on observation directions is further reduced (Examples 1 and 6).

### Preparation of Display Devices According to Examples 13 to 21

As a display device, iPad (registered trade name, manufactured by Apple Inc.) and TH-55FZ950 (manufactured by Panasonic Corporation) were prepared and used as display devices 1 and 2, respectively. The display device 1 is a liquid crystal display device that emits linearly polarized light, and the display device 2 is an organic light emitting diode (OLED) that emits linearly polarized light.

In addition, a λ/4 retardation plate 1 was prepared using the same method as that of a circularly polarizing plate 21 described in JP6276393B, except that the PET film with the underlayer 1 used for preparing the circularly polarized light reflection layer 1 was used instead of a polarizing plate 01 described in JP6276393B.

Regarding each of the decorative layers where the opening portions were provided that were prepared using the combinations shown in Table 2, the prepared circularly polarized light reflection layer was bonded using a pressure sensitive adhesive (SK2057, manufactured by Soken Chemical & Engineering Co., Ltd.) to a surface of the PMMA film where the decorative layer was not formed. Next, the PET film was peeled off. The amount of the pressure sensitive adhesive attached was adjusted such that the thickness of a layer (pressure sensitive adhesive layer) formed of the pressure sensitive adhesive was 25 μm.

Further, the prepared λ/4 retardation plate 1 was bonded using a pressure sensitive adhesive (SK2057, manufactured by Soken Chemical & Engineering Co., Ltd.) to the circularly polarized light reflection layer, the PET film was peeled off, and a pressure sensitive adhesive (SK2057, manufactured by Soken Chemical & Engineering Co., Ltd.) was bonded. By bonding the decorative sheet including the λ/4 retardation plate to the above-described display device using the pressure sensitive adhesive, display devices according to Examples 13 to 21 were prepared. The amount of the pressure sensitive adhesive attached was adjusted such that the thickness of a layer (pressure sensitive adhesive layer) formed of the pressure sensitive adhesive was 25 μm.

Here, the angle between the absorption axis of the visible-side polarizing plate of the display device and the slow axis of the λ/4 retardation plate 1 was any one of 45° clockwise or counterclockwise, the λ/4 retardation plate and the decorative sheet were disposed in this order on the display device, and the layers were bonded to obtain axial arrangement where there was no problem in the color of an image displayed by the display device.

### Preparation of Display Device According to Example 22

Regarding the decorative layer 6 where the opening portions were provided that were prepared using the combinations shown in Table 1, the prepared circularly polarized light reflection layer 1 was bonded using a pressure sensitive adhesive (Opteria D692, manufactured by Lintec Corporation) to a surface of the PMMA film where the decorative layer was not formed. Next, the PET film was peeled off. The amount of the pressure sensitive adhesive attached was adjusted such that the thickness of a layer (pressure sensitive adhesive layer) formed of the pressure sensitive adhesive was 15 μm.

Further, the prepared λ/4 retardation plate 1 was bonded using a pressure sensitive adhesive (SK2057, manufactured by Soken Chemical & Engineering Co., Ltd.) to the circularly polarized light reflection layer, the PET film was peeled off, and a pressure sensitive adhesive having a thickness of 25 μm was bonded. By bonding the decorative sheet including the λ/4 retardation plate to the above-described display device using the pressure sensitive adhesive, a display device according to Example 22 was prepared. The amount of the pressure sensitive adhesive attached was adjusted such that the thickness of a layer (pressure sensitive adhesive layer) formed of the pressure sensitive adhesive was 25 μm.

Here, the angle between the absorption axis of the polarizing plate of the display device and the slow axis of the λ/4 retardation plate 1 was any one of 45° clockwise or 45° counterclockwise, the λ/4 retardation plate and the decorative sheet were disposed in this order on the display device, and the layers were bonded to obtain axial arrangement where there was no problem in the color of an image displayed by the display device.

### Preparation of Decorative Sheet According to Comparative Example 3

Regarding the decorative layer 7 where the opening portions were provided, the prepared λ/4 retardation plate 1 was bonded using a pressure sensitive adhesive (SK2057, manufactured by Soken Chemical & Engineering Co., Ltd.) to a surface of the PMMA film where the decorative layer was not formed, the PET film was peeled off, and subsequently the pressure sensitive adhesive (SK2057, manufactured by Soken Chemical & Engineering Co., Ltd.) was bonded. By bonding the decorative sheet including the λ/4 retardation plate to the above-described display device using the pressure sensitive adhesive, a display device according to Comparative Example 3 was prepared. The amount of the pressure sensitive adhesive attached was adjusted such that the thickness of each of the layers (pressure sensitive adhesive layer) formed of the pressure sensitive adhesive was 25 μm.

### Preparation of Decorative Sheet according to Comparative Example 4

Further, the prepared λ/4 retardation plate 1 was bonded using a pressure sensitive adhesive (SK2057, manufactured by Soken Chemical & Engineering Co., Ltd.) to the prepared circularly polarized light reflection layer 1, the PET film was peeled off, and a pressure sensitive adhesive (SK2057, manufactured by Soken Chemical & Engineering Co., Ltd.) was bonded. By bonding the decorative sheet including the λ/4 retardation plate to the above-described display device using the pressure sensitive adhesive, a display device according to Comparative Example 4 was prepared. The amount of the pressure sensitive adhesive attached was adjusted such that the thickness of each of the layers (pressure sensitive adhesive layer) formed of the pressure sensitive adhesive was 25 μm.

Here, the angle between the absorption axis of the polarizing plate of the display device and the slow axis of the λ/4 retardation plate 1 was any one of 45° clockwise or 45° counterclockwise, the λ/4 retardation plate and the decorative sheet were disposed in this order on the display device, and the layers were bonded to obtain axial arrangement where there was no problem in the color of an image displayed by the display device.

<Evaluation of Display Device>

The prepared display device was evaluated as follows.

(Evaluation of Visibility during Display OFF (Turn-Off))

The display device was caused to enter a display OFF (turn-off) state, and in a case where the decorative sheet was seen from the front and from a 45 degree oblique direction, the visibility of the decorative pattern was evaluated based on the following standards.
A: the decorative pattern can be clearly visually recognized.
B: the decorative pattern can be visually recognized.
C: the visibility of the decorative pattern is poor (unclear), which is not allowable.

(Evaluation of Tint Change during Display OFF (Turn-Off))

The display device was caused to enter a display OFF (turn-off) state and was observed from a 15 degree oblique direction and from a 45 degree oblique direction. A tint change from the front was checked by visual inspection and was evaluated based on the following standards.
A: a tint difference of the decorative pattern between the front and the 15 degree oblique direction or the 45 degree oblique direction does not attract attention at all.
B: a tint difference of the decorative pattern between the front and the 15 degree oblique direction or the 45 degree oblique direction is slightly visually recognized.
C: a tint difference of the decorative pattern between the front and the 15 degree oblique direction or the 45 degree oblique direction is visually recognized but is allowable.
D: a tint difference of the decorative pattern between the front and the 15 degree oblique direction or the 45 degree oblique direction is clearly visually recognized which is not allowable).

(Evaluation of Front Transmittance during Display ON)

A front brightness LO in a state where the decorative sheet was not mounted on the display device and a front brightness L in a state where the decorative sheet was mounted on the display device were measured. Next, a transmittance was estimated from L/LO and was evaluated based on the following standards.
A: the transmittance with respect to the state where the decorative film is not present is 60% or more.
B: the transmittance with respect to the state where the decorative film is not present is 30% or more and less than 60%.
C: the transmittance with respect to the state where the decorative film is not present is less than 30%.

(Evaluation of Visibility-Corrected Circularly Polarized Light Transmittance in case where Only Decorative Sheet Was Provided)

A decorative sheet including the λ/4 retardation plate 1 that was not bonded to each of the display devices according to Examples and Comparative Examples was prepared, the polarizing plate was bonded to the λ/4 retardation plate 1 side using a pressure sensitive adhesive (SK2057, manufactured by Soken Chemical & Engineering Co., Ltd.) to prepare the decorative sheet with the polarizing plate. The amount of the pressure sensitive adhesive attached was adjusted such that the thickness of a layer (pressure sensitive adhesive layer) formed of the pressure sensitive adhesive was 25 μm.

Here, the λ/4 retardation plate 1 and the polarizing plate were bonded such that the axial arrangement between the absorption axis of the polarizing plate and the slow axis of the λ/4 retardation plate in the decorative sheet with the polarizing plate was the same as the axial arrangement between the absorption axis of the visible-side polarizing plate and the slow axis of the λ/4 retardation plate in each of the display devices according to Examples and Comparative Examples.

The prepared decorative sheet with the polarizing plate was disposed in a spectrophotometer (UV-3150, manufactured by Shimadzu Corporation), measurement light was incident from the polarizing plate, circularly polarized light was used as incidence light to measure a transmission spectrum of the circularly polarized light of the decorative sheet with the polarizing plate in a wavelength range of 380 to 780 nm, and the visibility was corrected using a 2 degree field of view (C light source) according to JIS Z8701 to calculate a visibility-corrected circularly polarized light transmittance. The baseline was corrected using the PMMA film with the polarizing plate that was prepared using the same method as that of preparing each of the decorative sheets with the polarizing plate, except that the PMMA film used for preparing the decorative sheet was used instead of the decorative sheet.

TABLE 2

| | | | | | | | | | | | | | Compar- | Compar- |
|---|---|---|---|---|---|---|---|---|---|---|---|---|---|---|
| | | | | | | | | | | | | | ative | ative |
| | | | Ex- | Ex- | Ex- | Ex- | Ex- | Ex- | Ex- | Ex- | Ex- | Ex- | Ex- | Ex- |
| | | | ample | ample | ample | ample | ample | ample | ample | ample | ample | ample | ample | ample |
| | | | 13 | 14 | 15 | 16 | 17 | 18 | 19 | 20 | 21 | 22 | 3 | 4 |
| Deco- | Kind of | | 1 | 1 | 1 | 1 | 1 | 2 | 3 | 4 | 5 | 6 | 7 | — |
| rative | decorative | | | | | | | | | | | | | |
| layer | layer where | | | | | | | | | | | | | |
| where | opening portions | | | | | | | | | | | | | |
| opening | are provided | | | | | | | | | | | | | |
| portions | Decorative | | Grain | Grain | Grain | Grain | Grain | Marble | Grain | Grain | Grain | Grain | Grain | — |
| are | pattern | | | | | | | | | | | | | |
| provided | Diameter | | 40 | 40 | 40 | 40 | 40 | 40 | 300 | 10 | 500 | 300 | 25 | — |
| | of opening | | | | | | | | | | | | | |
| | portion [μm] | | | | | | | | | | | | | |
| | (Distance | | 3.8 | 3.8 | 3.8 | 3.8 | 3.8 | 3.8 | 0.5 | 15.0 | 0.30 | 0.30 | — | — |
| | between | | | | | | | | | | | | | |
| | ch liquid | | | | | | | | | | | | | |
| | crystal layer | | | | | | | | | | | | | |
| | and decorative | | | | | | | | | | | | | |
| | layer)/ | | | | | | | | | | | | | |
| | (Diameter | | | | | | | | | | | | | |
| | of opening | | | | | | | | | | | | | |
| | portion) | | | | | | | | | | | | | |
| | Visibility- | | 45 | 45 | 45 | 45 | 45 | 33 | 70 | 45 | 75 | 70 | 65 | |
| | corrected | | | | | | | | | | | | | |
| | transmittance | | | | | | | | | | | | | |
| | [%] | | | | | | | | | | | | | |
| Circu- | Kind of | | 1 | 1 | 2 | 3 | 4 | 5 | 1 | 6 | 1 | 1 | — | 1 |
| larly | circularly | | | | | | | | | | | | | |
| polar- | polarized light | | | | | | | | | | | | | |
| ized | reflection layer | | | | | | | | | | | | | |
| | Decorative | | Grain | Grain | Grain | Grain | Grain | Marble | Grain | Grain | Grain | Grain | — | Grain |
| light | pattern | | | | | | | | | | | | | |
| reflec- | Average | | 7 | 7 | 7 | ∞ | 54 | 1.0 | 7 | 12 | 7 | 7 | — | 7 |
| tion | value of | | | | | (Specular | | | | | | | | |
| layer | peak-to-peak | | | | | reflection) | | | | | | | | |
| (ch | distances | | | | | | | | | | | | | |
| liquid | of waving | | | | | | | | | | | | | |
| crystal | structure [μm] | | | | | | | | | | | | | |
| layer) | Maximum value | | 31 | 31 | 31 | 0 | 31 | 8 | 31 | 41 | 31 | 31 | — | 31 |
| | reflectivity | | | | | | | | | | | | | |
| | excluding | | | | | | | | | | | | | |
| | specular | | | | | | | | | | | | | |
| | of integral | | | | | | | | | | | | | |
| | reflection | | | | | | | | | | | | | |
| | component in | | | | | | | | | | | | | |
| | visible range [%] | | | | | | | | | | | | | |
| | Change of | | Present | Present | None | None | Present | Present | Present | Present | Present | Present | — | Present |
| | helical pitch in | | | | | | | | | | | | | |
| | film thickness | | | | | | | | | | | | | |
| | direction | | | | | | | | | | | | | |
| λ/4 retardation plate | | | Present | Present | Present | Present | Present | Present | Present | Present | Present | Present | Present | Present |
| Polarizing plate | | | Display | Display | Display | Display | Display | Display | Display | Display | Display | Display | Display | Display |
| Visibility-corrected circularly | | | device 1 | device 2 | device 2 | device 2 | device 2 | device 2 | device 2 | device 2 | device 2 | device 2 | device 2 | device 2 |
| polarized light transmittance | | | 36% | 36% | 36% | 36% | 32% | 27% | 66% | 25% | 72% | 66% | 41% | — |
| in decorative sheet alone | | | | | | | | | | | | | | |
| Evalu- | Visibility | Front | A | A | A | A | A | A | A | A | A | A | C | A |
| ation | during | 45 degree | A | A | A | B | B | A | A | A | A | A | C | A |
| of | off | oblique | | | | | | | | | | | | |
| deco- | (turn- | direction | | | | | | | | | | | | |
| rative | off) of | | | | | | | | | | | | | |
| sheet | display | | | | | | | | | | | | | |
| alone | device | | | | | | | | | | | | | |
| | Tint | 15 degree | A | A | A | C | B | A | A | A | A | A | — | B |
| | change | oblique | | | | | | | | | | | | |
| | during | direction | | | | | | | | | | | | |
| | off | 45 degree | A | A | A | C | B | A | B | A | C | C | — | D |
| | (turn- | oblique | | | | | | | | | | | | |
| | off) of | direction | | | | | | | | | | | | |
| | display | | | | | | | | | | | | | |
| | device | | | | | | | | | | | | | |

| | | | | | | | | | | | | |
|---|---|---|---|---|---|---|---|---|---|---|---|---|
| Front | B | B | B | B | B | C | A | C | A | A | A | A |
| transmittance | | | | | | | | | | | | |
| during display | | | | | | | | | | | | |
| on of display | | | | | | | | | | | | |
| device | | | | | | | | | | | | |

As shown in Table 2, it was clarified that, in a case where the decorative sheet according to the embodiment of the present invention is applied to a display device, a tint change depending on observation directions is small, and the visibility of a pattern in any observation direction is excellent (Examples).

It was clarified from a comparison between Examples 14 and 17 and a comparison between Examples 15 and 16 that, in a case where an average value of peak-to-peak distances of the waving structure is in a range of 0.5 to 50 μm, a tint change depending on observation directions is further reduced, and the visibility of a pattern in any observation direction is further improved (Examples 14 and 15).

It was clarified from a comparison between Examples 15 and 16 that, in a case where a maximum value of an integral reflectivity of the circularly polarized light reflection layer excluding a specular reflection component in a wavelength range of 380 to 780 nm is 7% or more, a tint change depending on observation directions is further reduced, and the visibility of a pattern in any observation direction is further improved (Example 15).

It was clarified from a comparison between Examples 14, 19, and 21 that, in a case where the visibility-corrected transmittance of the decorative layer in a visible range is 70% or less, a tint change depending on observation directions is further reduced (Examples 14 and 19).

It was found from a comparison between Examples 13 to 22 that, in a case where a visibility-corrected transmittance of circularly polarized light of the decorative sheet in a visible range is 30% or more, the transmittance during the display ON (turn-on) of the display device is excellent, and the visibility of an image displayed by the display device is improved (Examples 13 to 17, 19, and 21 and 22).

### EXPLANATION OF REFERENCES

1: decorative sheet
10: first support
12: underlayer
14: circularly polarized light reflection layer
20: second support
22a: opening portion
30: substrate
32, 34: cholesteric liquid crystal layer
B: bright portion
D: dark portion
p: distance
L: diameter

What is claimed is:

1. A decorative sheet comprising:
a circularly polarized light reflection layer; and
a decorative layer that is disposed on the circularly polarized light reflection layer and where an opening portion is provided.

2. The decorative sheet according to claim 1,
wherein the circularly polarized light reflection layer exhibits selective reflection in a visible range and has a stripe pattern of bright portions and dark portions observed with a scanning electron microscope in a cross-section,
the stripe pattern has a waving structure, and
the waving structure refers to a structure in which at least one region M where an absolute value of a tilt angle of a continuous line of the bright portions or the dark portions in the stripe pattern with respect to a plane of the circularly polarized light reflection layer is 5° or more is present, and peaks or valleys having a tilt angle of 0° are specified at two points most adjacent to each other with the region M sandwiched between the two points.

3. The decorative sheet according to claim 2,
wherein an average value of peak-to-peak distances of the waving structure is 0.5 to 50 μm,
the peak-to-peak distance of the waving structure refers to a value obtained by measuring a distance in a plane direction of the circularly polarized light reflection layer between the peaks or the valleys having a tilt angle of 0° at the two points most adjacent to each other with the region M sandwiched between the two points and calculating an arithmetic mean value of distance values at all film thicknesses in a case where a length of the circularly polarized light reflection layer in a major axis direction of the cross-section is 100 μm.

4. The decorative sheet according to claim 1,
wherein a maximum value of an integral reflectivity of the circularly polarized light reflection layer excluding a specular reflection component in a wavelength range of 380 to 780 nm is 7% or more.

5. The decorative sheet according to claim 1,
wherein the circularly polarized light reflection layer includes a cholesteric liquid crystal layer having a pitch gradient structure that is a structure in which a helical pitch changes in a thickness direction.

6. The decorative sheet according to claim 1,
wherein a diameter of the opening portion is 500 μm or less.

7. The decorative sheet according to claim 1,
wherein a visibility-corrected transmittance of the decorative layer in a visible range is 70% or less.

8. The decorative sheet according to claim 1,
wherein a visibility-corrected transmittance of circularly polarized light in a visible range is 30% or more.

9. The decorative sheet according to claim 1, further comprising:
a λ/4 retardation plate or a circularly polarizing plate on a surface side of the circularly polarized light reflection layer opposite to the decorative layer.

10. A display device comprising:
a display element; and
the decorative sheet according to claim 1 that is disposed on the display element.

11. The display device according to claim 10,
wherein emitted light of the display element is linearly polarized light.

12. The display device according to claim 11, which is a liquid crystal display device or an organic electroluminescent display device.

13. An automobile interior material comprising:
the decorative sheet according to claim 1.

14. An automobile interior material comprising:
he display device according to claim 10.

15. The decorative sheet according to claim 2,
wherein a maximum value of an integral reflectivity of the circularly polarized light reflection layer excluding a specular reflection component in a wavelength range of 380 to 780 nm is 7% or more.

16. The decorative sheet according to claim 2,
wherein the circularly polarized light reflection layer includes a cholesteric liquid crystal layer having a pitch gradient structure that is a structure in which a helical pitch changes in a thickness direction.

17. The decorative sheet according to claim 2,
wherein a diameter of the opening portion is 500 μm or less.

18. The decorative sheet according to claim 2,
wherein a visibility-corrected transmittance of the decorative layer in a visible range is 70% or less.

19. The decorative sheet according to claim 2,
wherein a visibility-corrected transmittance of circularly polarized light in a visible range is 30% or more.

20. The decorative sheet according to claim 2, further comprising:
a λ/4 retardation plate or a circularly polarizing plate on a surface side of the circularly polarized light reflection layer opposite to the decorative layer.
